(19) United States
(12) Patent Application Publication
(10) Pub. No.: US 2026/0304954 A1
(43) Pub. Date: Oct. 1, 2026

(54) SEMICONDUCTOR STRUCTURE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 19/093,886

(22) Filed: Mar. 28, 2025

(51) Int. Cl. H10D 84/90; H10D 89/10

(52) U.S. Cl. CPC H10D 84/966; H10D 84/953; H10D 84/981; H10D 89/10

(57) ABSTRACT

A semiconductor structure includes a transistor including channel layers vertically stacked from each other, a gate structure interfacing at least three surfaces of each of the channel layers, and a first source/drain feature and a second source/drain feature on opposite sides of the gate structure. The semiconductor structure further includes a first source/drain contact over and electrically connected to the first source/drain feature and a second source/drain contact under and electrically connected to the second source/drain feature. A bottom surface of the first source/drain contact is lower than a bottom surface of a topmost channel layer of the channel layers. A top surface of the second source/drain contact is higher than a top surface of a bottommost channel layer of the channel layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various logic or STD cells that can be implemented in the logic region of the IC chip of FIG. 1 in accordance with some embodiments of the present disclosure.

FIGS. 3 and 4 illustrate circuit schematics of a memory cell that can be implemented in the memory region of the IC chip of FIG. 1, in accordance with some embodiments of the present disclosure.

FIG. 5 illustrates a perspective view of an embodiment of a GAA transistor in transistor cells, in accordance with some embodiments of the present disclosure.

FIGS. 6A and 6B are top views (or layouts) of a semiconductor structure that can be one embodiment of transistor cells implemented in the logic region or the memory region of the IC chip, in which FIG. 6A illustrates the features in the device region and the frontside interconnection structure, and FIG. 6B illustrates the features in the device region and the backside interconnection structure.

FIGS. 6C and 6D are X-Z cross-sectional views of the semiconductor structure along lines C-C′ and D-D′ of FIGS. 6A and 6B, respectively, in accordance with some embodiments of the present disclosure.

FIGS. 6E, 6F, 6G, and 6H are Y-Z cross-sectional view of the semiconductor structure along lines E-E′, F-F′, G-G′, and H-H′ of FIGS. 6A and 6B, respectively, in accordance with some embodiments of the present disclosure.

FIGS. 7 and 8 illustrate perspective views of a workpiece at various fabrication stages for the semiconductor structure, in accordance with some embodiments of the present disclosure.

FIGS. 9, 13, and 17 illustrate top views (or layouts) of the workpiece at various fabrication stages for the semiconductor device, in accordance with some embodiments of the present disclosure.

FIGS. 10A, 11A, 12A illustrate X-Z cross-sectional views of the workpiece at various fabrication stages for the semiconductor structure along a line C-C′ of FIG. 9, respectively, in accordance with some embodiments of the present disclosure.

FIGS. 10B, 11B, 12B illustrate X-Z cross-sectional views of the workpiece at various fabrication stages for the semiconductor structure along a line D-D′ of FIG. 9, respectively, in accordance with some embodiments of the present disclosure.

FIGS. 10C, 11C, 12C illustrate Y-Z cross-sectional views of the workpiece at various fabrication stages for the semiconductor structure along a line E-E′ of FIG. 9, respectively, in accordance with some embodiments of the present disclosure.

FIGS. 10D, 11D, 12D illustrate Y-Z cross-sectional views of the workpiece at various fabrication stages for the semiconductor structure along a line F-F′ of FIG. 9, respectively, in accordance with some embodiments of the present disclosure.

FIGS. 10E, 11E, 12E illustrate Y-Z cross-sectional views of the workpiece at various fabrication stages for the semiconductor structure along a line G-G′ of FIG. 9, respectively, in accordance with some embodiments of the present disclosure.

FIGS. 10F, 11F, 12F illustrate Y-Z cross-sectional views of the workpiece at various fabrication stages for the semiconductor structure along a line H-H′ of FIG. 9, respectively, in accordance with some embodiments of the present disclosure.

FIGS. 14A, 15A, 16A illustrate X-Z cross-sectional views of the workpiece at various fabrication stages for the semiconductor structure along a line C-C′ of FIG. 13, respectively, in accordance with some embodiments of the present disclosure.

FIGS. 14B, 15B, 16B illustrate X-Z cross-sectional views of the workpiece at various fabrication stages for the semiconductor structure along a line D-D′ of FIG. 13, respectively, in accordance with some embodiments of the present disclosure.

FIGS. 14C, 15C, 16C illustrate Y-Z cross-sectional views of the workpiece at various fabrication stages for the semiconductor structure along a line E-E′ of FIG. 13, respectively, in accordance with some embodiments of the present disclosure.

FIGS. 14D, 15D, 16D illustrate Y-Z cross-sectional views of the workpiece at various fabrication stages for the semiconductor structure along a line F-F′ of FIG. 13, respectively, in accordance with some embodiments of the present disclosure.

FIGS. 14E, 15E, 16E illustrate Y-Z cross-sectional views of the workpiece at various fabrication stages for the semiconductor structure along a line G-G′ of FIG. 13, respectively, in accordance with some embodiments of the present disclosure.

FIGS. 14F, 15F, 16F illustrate Y-Z cross-sectional views of the workpiece at various fabrication stages for the semiconductor structure along a line H-H′ of FIG. 13, respectively, in accordance with some embodiments of the present disclosure.

FIGS. 18A, 19A, 20A illustrate X-Z cross-sectional views of the workpiece at various fabrication stages for the semiconductor structure along a line C-C′ of FIG. 17, respectively, in accordance with some embodiments of the present disclosure.

FIGS. 18B, 19B, 20B illustrate X-Z cross-sectional views of the workpiece at various fabrication stages for the semiconductor structure along a line D-D′ of FIG. 17, respectively, in accordance with some embodiments of the present disclosure.

FIGS. 18C, 19C, 20C illustrate Y-Z cross-sectional views of the workpiece at various fabrication stages for the semiconductor structure along a line E-E′ of FIG. 17, respectively, in accordance with some embodiments of the present disclosure.

FIGS. 18D, 19D, 20D illustrate Y-Z cross-sectional views of the workpiece at various fabrication stages for the semiconductor structure along a line F-F′ of FIG. 17, respectively, in accordance with some embodiments of the present disclosure.

FIGS. 18E, 19E, 20E illustrate Y-Z cross-sectional views of the workpiece at various fabrication stages for the semiconductor structure along a line G-G′ of FIG. 17, respectively, in accordance with some embodiments of the present disclosure.

FIGS. 18F, 19F, 20F illustrate Y-Z cross-sectional views of the workpiece at various fabrication stages for the semiconductor structure along a line H-H′ of FIG. 17, respectively, in accordance with some embodiments of the present disclosure.

FIGS. 21A and 21B are top views (or layouts) of a semiconductor structure that can be one embodiment of transistor cells implemented in the logic region or the memory region of the IC chip, in which FIG. 21A illustrates the features in the device region and the frontside interconnection structure, and FIG. 21B illustrates the features in the device region and the backside interconnection structure.

FIGS. 21C and 21D are X-Z cross-sectional views of the semiconductor structure along lines C-C′ and D-D′ of FIGS. 21A and 21B, respectively, in accordance with some alternative embodiments of the present disclosure.

FIGS. 21E and 21F are Y-Z cross-sectional view of the semiconductor structure along lines E-E′ and F-F′ of FIGS. 21A and 21B, respectively, in accordance with some alternative embodiments of the present disclosure.

FIGS. 22A and 22B are top views (or layouts) of a semiconductor structure that can be one embodiment of transistor cells implemented in the logic region or the memory region of the IC chip, in which FIG. 22A illustrates the features in the device region and the frontside interconnection structure, and FIG. 22B illustrates the features in the device region and the backside interconnection structure.

FIGS. 22C and 22D are X-Z cross-sectional views of the semiconductor structure along lines C-C′ and D-D′ of FIGS. 22A and 22B, respectively, in accordance with some alternative embodiments of the present disclosure.

FIGS. 22E and 22F are Y-Z cross-sectional view of the semiconductor structure along lines E-E′ and F-F′ of FIGS. 22A and 22B, respectively, in accordance with some alternative embodiments of the present disclosure.

FIGS. 23A and 23B are top views (or layouts) of a semiconductor structure that can be one embodiment of transistor cells implemented in the logic region or the memory region of the IC chip, in which FIG. 23A illustrates the features in the device region and the frontside interconnection structure, and FIG. 23B illustrates the features in the device region and the backside interconnection structure.

FIGS. 23C and 23D are X-Z cross-sectional views of the semiconductor structure along lines C-C′ and D-D′ of FIGS. 23A and 23B, respectively, in accordance with some alternative embodiments of the present disclosure.

FIGS. 23E and 23F are Y-Z cross-sectional view of the semiconductor structure along lines E-E′ and F-F′ of FIGS. 23A and 23B, respectively, in accordance with some alternative embodiments of the present disclosure.

FIGS. 24A and 24B are top views (or layouts) of a semiconductor structure that can be one embodiment of transistor cells implemented in the logic region or the memory region of the IC chip, in which FIG. 24A illustrates the features in the device region and the frontside interconnection structure, and FIG. 24B illustrates the features in the device region and the backside interconnection structure.

FIGS. 24C and 24D are X-Z cross-sectional views of the semiconductor structure along lines C-C′ and D-D′ of FIGS. 24A and 24B, respectively, in accordance with some alternative embodiments of the present disclosure.

FIGS. 24E and 24F are Y-Z cross-sectional view of the semiconductor structure along lines E-E′ and F-F′ of FIGS. 24A and 24B, respectively, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including VDD and VSS conductors in the backside interconnection structure and source/drain contacts deep into source/drain features, such that the routing complexity, the current crowding, and source/drain resistance are reduced. The details of the structure and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

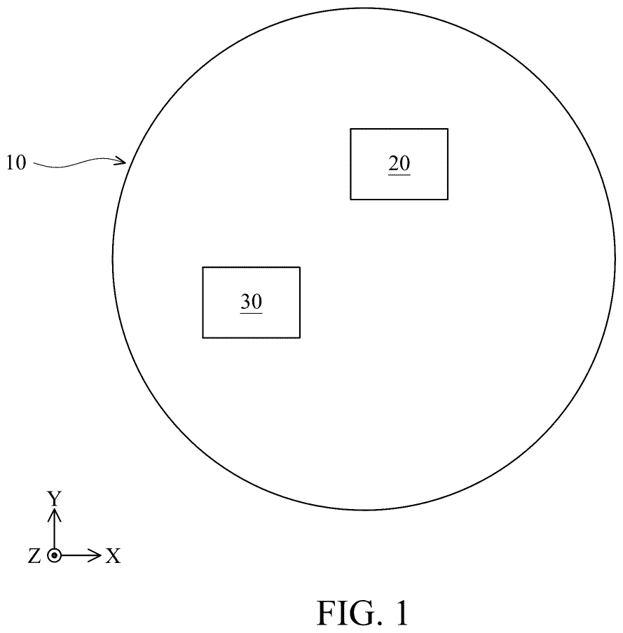

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), N-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of transistor cells for memory (i.e., memory cells), each of which includes transistors and interconnection structures (also referred to as routing structures) that combine to provide a storage device and/or a storage function, such as a flip flop, a latch, other suitable semiconductor devices, or a combination thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or a combination thereof.

The logic region 30 can include an array of transistor cells for logic (i.e., logic cells or standard (STD) cells). The logic cells or STD cells may include transistors and interconnection structures that combine to provide a logic device and/or a logic function, such as an inverter, an AND, a NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

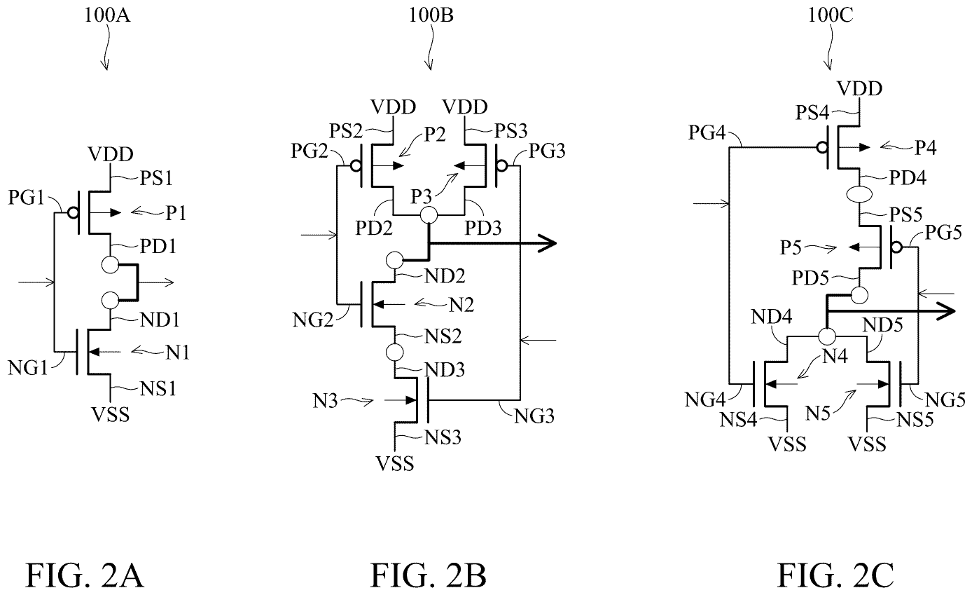

FIGS. 2A to 2E are circuit schematics of various logic or STD cells in the array of transistor cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

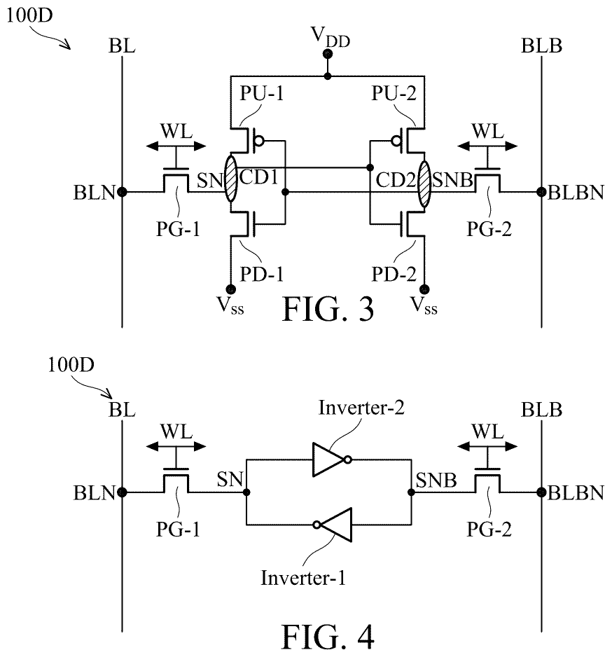

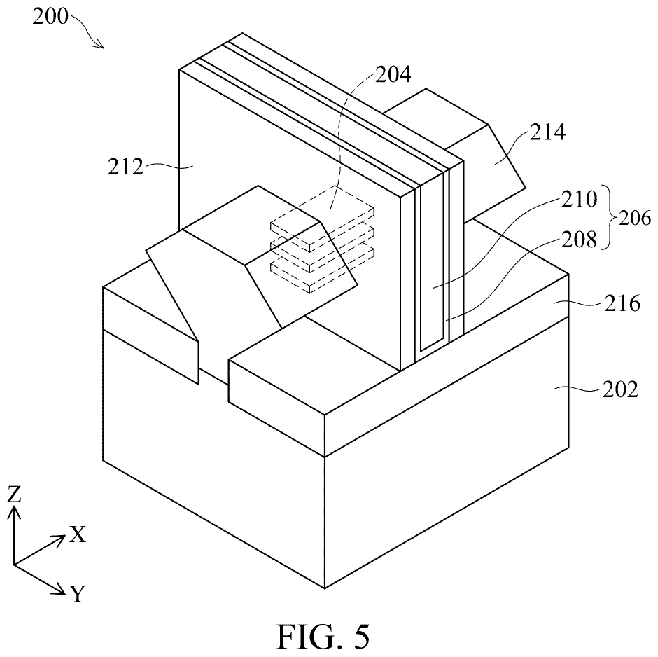

FIGS. 3 and 4 are circuit schematics of a memory cell for SRAM (i.e., SRAM cell) in the array of transistor cells in the memory region 20 of the IC chip 10, in accordance with some embodiments of the present disclosure. The circuit diagram of SRAM cell is merely exemplary, and in some embodiments, each of SRAM cells in the array is configured with an SRAM circuit similar to the SRAM cell 100D as shown in FIGS. 3 and 4. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inveter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Invereter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground). A gate of pull-up transistor PU-1 interposes a source, which is electrically coupled to the first power supply voltage via a voltage node (or voltage source) VDD, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) VSS, and the first common drain. A gate of pull-up transistor PU-2 interposes a source, which is electrically coupled to the first power supply voltage via voltage node VDD, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node VSS, and the second common drain. The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1. A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2. Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL.

In some embodiments, SRAM cells are single-port SRAMs. In some embodiments, SRAM cells are configured as multi-port SRAMs, such as dual-port SRAMs, and/or with more or less transistors than depicted, such as 8T SRAMs. FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the logic cells and the SRAM cells discussed above is constructed by transistors, such that the logic cells and the SRAM cells herein may also be referred to as transistor cells. The transistors may be planar transistors, fin field-effect transistor (FinFET) transistors, gate-all-around (GAA) transistors, nano-wire transistors, nanosheet transistors, or a combination thereof. For the sake of providing an example, an exemplary GAA transistor is illustrated in FIG. 5. However, it should be understood that the application should not be limited to a particular type of device, except as specifically claimed.

Referring to FIG. 5, a perspective view of an exemplary GAA transistor 200 is illustrated. The GAA transistor 200 is formed over a substrate 202. The substrate 202 may contains a semiconductor material, such as bulk silicon (Si).

The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

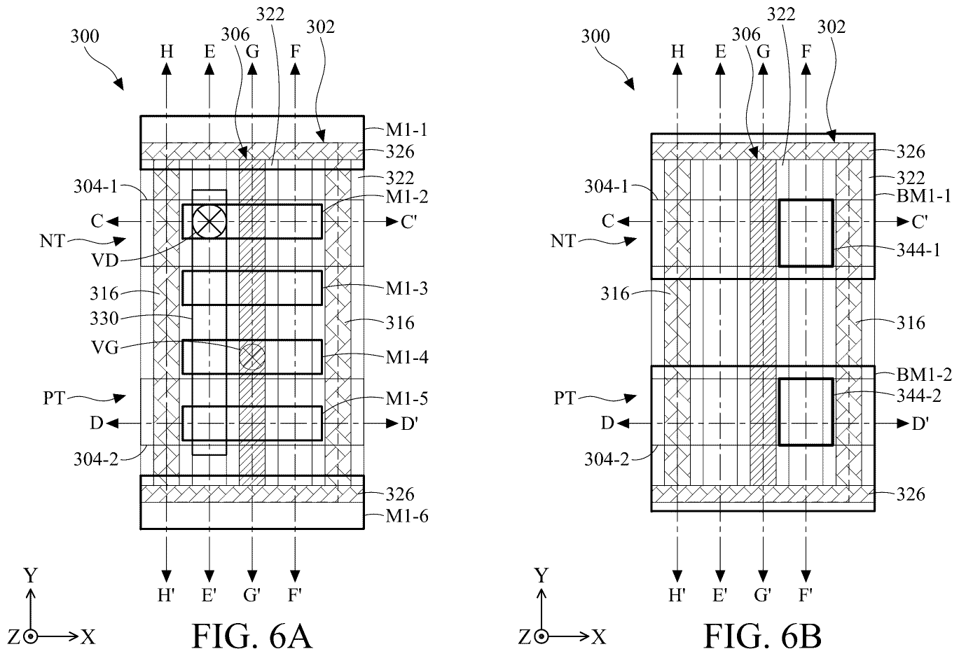

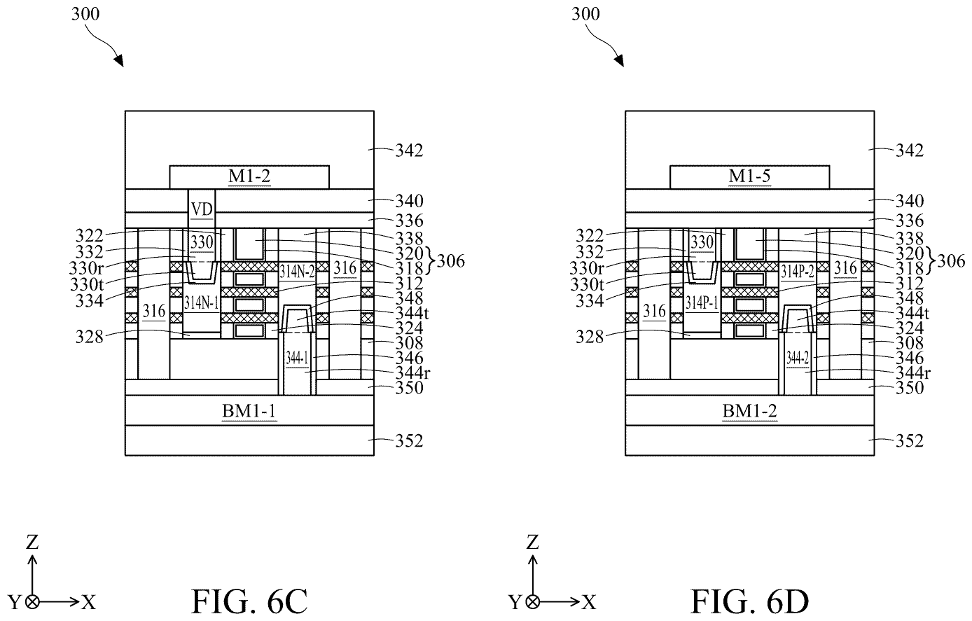

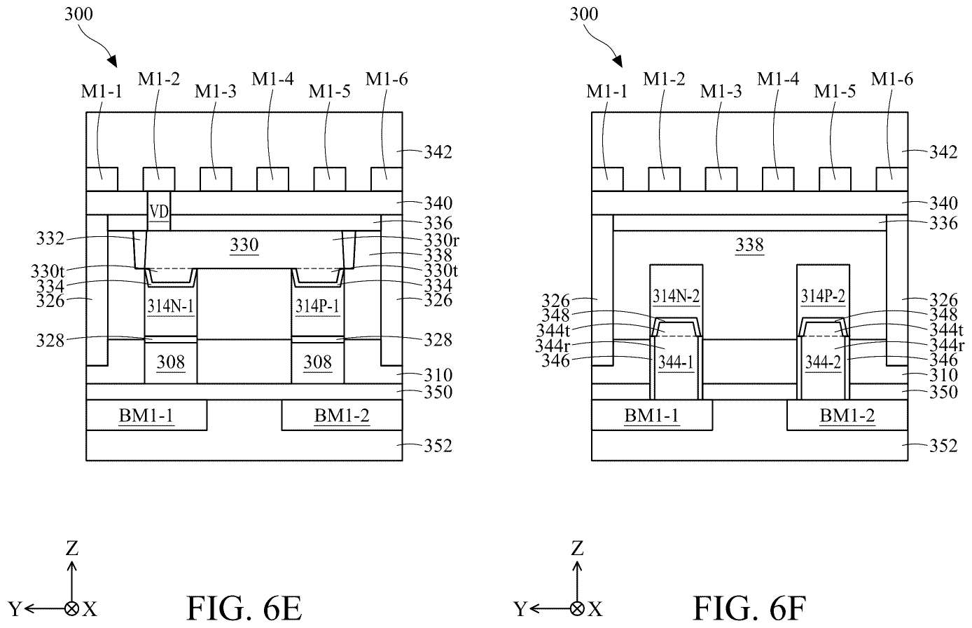

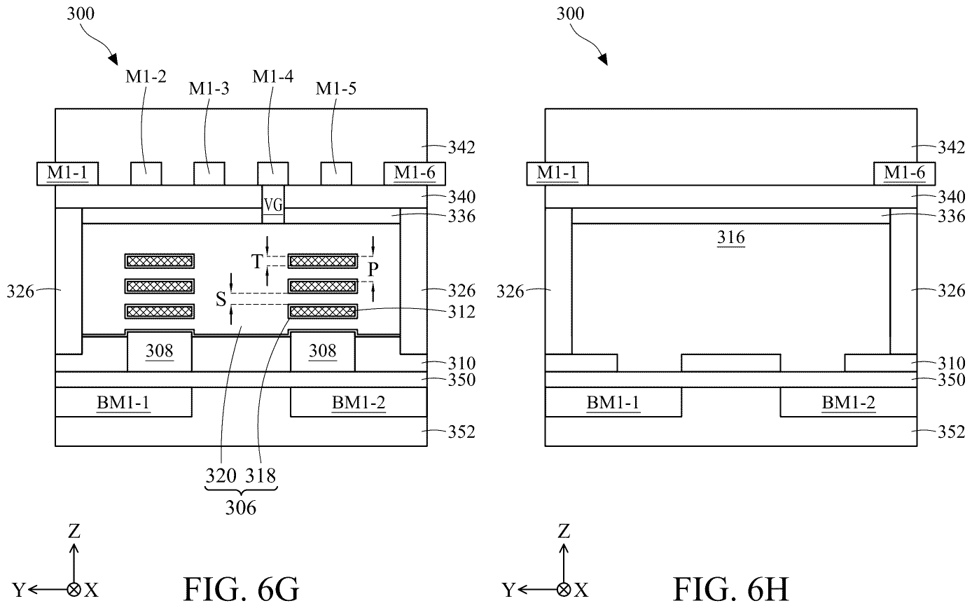

The GAA transistor 200 further includes a gate structure 206 including a gate dielectric layer 208 and a gate electrode layer 210. The gate dielectric layer 208 wraps around the nanostructures 204 and the gate electrode layer 210 wraps around the gate dielectric layer 208 (not shown in FIG. 5, may refer to FIGS. 6C, 6D, and 6G). As shown in FIG. 5, gate spacers 212 are on sidewalls of the gate structure 206 and over the nanostructures 204 (not shown in FIG. 5, may refer to FIGS. 6C and 6D)

The GAA transistor 200 further includes source/drain features 214. As shown in FIG. 5, two source/drain features 214 are on opposite sides of the gate structure 206. The nanostructures 204 (dash lines) extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

Isolation feature 216 is over the substrate 202 and under the gate dielectric layer 208, the gate electrode layer 210, and the gate spacers 212. The isolation feature 216 is used for isolating the GAA transistor 200 from other devices. In some embodiments, the isolation feature 216 may include different structures, such as shallow trench isolation (STI) structure, deep trench isolation (DTI) structure. Therefore, the isolation feature 216 is also referred as to as a STI feature or DTI feature.

FIGS. 6A and 6B are top views (or layouts) of a semiconductor structure 300 that can be one embodiment of transistor cells implemented in the memory region 20 or the logic region 30 of the IC chip 10, in which FIG. 6A illustrates the features in the device region and the frontside interconnection structure, and FIG. 6B illustrates the features in the device region and the backside interconnection structure. FIGS. 6C and 6D are X-Z cross-sectional views of the semiconductor structure 300 along lines C-C′ and D-D′ of FIGS. 6A and 6B, respectively, in accordance with some embodiments of the present disclosure. FIGS. 6E, 6F, 6G, and 6H are Y-Z cross-sectional view of the semiconductor structure 300 along lines E-E′, F-F′, G-G′, and H-H′ of FIGS. 6A and 6B, respectively, in accordance with some embodiments of the present disclosure.

The semiconductor structure 300 may include transistor cells, for example, the logic cells and memory cells. As discussed above, the transistor cells may include logic/memory circuits or devices, including but not limited to logic/memory circuits such as inverters, NANDs, NORs, flip-flops, SRAM, or a combination thereof. For the sake of providing an example, the semiconductor structure 300 shows a transistor cell 302. The transistor cell 302 is inverter, as the inverter 100A discussed above. It should be understood that the transistor cell 302 is merely an example. The present disclosure applies to other types of transistor cells as well, for example cells including NORs, ANDs, ORs, flip-flops, SRAMs, or a combination thereof.

The transistor cell 302 in the semiconductor structure 300 includes active areas, such as active areas 304-1 and 304-2, (may be collectively referred to as the active areas 304) that extend lengthwise in the X-direction. Each of active areas 302 includes channel regions, source regions, and drain regions (where source regions and drain regions are collectively referred to as source/drain regions herein) of transistors (e.g., the GAA transistor 200) of the transistor cell 302, and portions of a substrate 308 under the channel regions, the source regions, and the drain regions.

The semiconductor structure 300 further includes a gate structure 306. The gate structure 306 extends lengthwise in the Y-direction perpendicular to the X-direction, as shown in FIGS. 6A and 6B. The gate structure 306 is disposed over the channel regions of the respective active areas 304-1 and 304-2 (i.e., the (vertically stacked) channel layers 312) and disposed between respective source/drain regions of the active areas 304-1 and 304-2 (i.e., source/drain features 314N and 314P). In some embodiments, the gate structure 306 interfaces at least three surfaces of each of the channel layers 312 in the channel regions of the active areas 304-1 and 304-2. More specifically, the gate structure 306 wraps and/or surrounds suspended, vertically stacked channel layers 312 in the channel regions of the active areas 304-1 and 304-2, respectively (as shown in FIG. 6G).

The active areas 304-1 and 304-2 and the gate structure 306 are configured to provide transistors for the transistor cell 302. As shown in FIGS. 6A and 6B, in the semiconductor structure 300, the gate structure 306 engages the active area 304-1 to construct an N-type transistor NT, and engages the active area 304-2 to construct a P-type transistor PT. In some embodiments, the N-type transistor NT and the P-type transistor PT may respectively be similar to the N-type transistor N1 and the P-type transistor P1 of the inverter 100A discussed above.

Therefore, the transistors used for the logic cells and/or the SRAM cells are formed. In some embodiments, in the semiconductor structure 300, the N-type transistor NT and the P-type transistor PT are arranged in the Y-direction and share the gate structure 306.

Referring to FIGS. 6C to 6H, the semiconductor structure 300 includes the substrate 308, over which the various features are formed, such as the gate structure 306, the channel layer 312, and the source/drain features 314N and 314P. The substrate 308 may contains a semiconductor material, such as bulk silicon (Si), such the substrate 308 may be referred to as the silicon substrate. In some other embodiments, the substrate 308 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs).

Similar to the isolation feature 216 discussed above, the semiconductor structure 300 further includes an isolation feature (or isolation structure) 310 isolating the adjacent active areas 304, as shown in FIGS. 6E to 6H. More specifically, as discussed above, the active areas 304 include the portions of the substrate 308 under the channel regions and the source/drain regions, as shown in FIGS. 6E to 6H, and the isolation feature 310 is formed between the portions of the substrate 308. In some aspects, the isolation feature 310 is formed around the active areas 304 (specifically, the portions of the substrate 308 under the channel regions and the source/drain regions). In some embodiments, the gate structure 306 is also formed over and interfacing a top surface of the isolation feature 310. For example, as shown FIG. 6G, the gate structure 306 is over and interfaces a top surface of the isolation feature 310.

The isolation feature 310 may include silicon oxide, silicon nitride, silicon oxynitride, other suitable isolation material (for example, including silicon, oxygen, nitrogen, carbon, or other suitable isolation constituent), or combinations thereof. The isolation feature 310 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

The semiconductor structure 300 further includes dielectric structures 316 for separating the transistor cell (constructed from the N-type transistor NT and the P-type transistor PT) from other devices or transistor cells (not shown) in the X-direction. The dielectric structures 316 extend lengthwise in the Y-direction. The dielectric structures 316 and the gate structure 306) are arranged in the X-direction. More specifically, as shown in FIGS. 6A, 6B, 6C, and 6D, two dielectric structures 316 and the transistor cell 302 (or the gate structure 306) are arranged in the X-direction. In some embodiments, in the transistor cell 302, two dielectric structures 316 are on opposites of the gate structure 306 in the X-direction. Furthermore, the dielectric structures 316 extend deep into the isolation feature 310. As shown in FIGS. 6C, 6D, and 6H, bottommost surfaces of the dielectric structures 316 are lower than top surfaces of the isolation feature 310 and a bottom surface of the gate structure 306.

The dielectric structures 316 may be made of electrically insulating materials (e.g., dielectric materials) to provide electrical isolation between various circuit cells. In some embodiments, the dielectric structures 316 may be single dielectric layer or multiple layers and selected from a group consisting of SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

Each of the transistors in the semiconductor structure 300 (e.g., the N-type transistor NT and the P-type transistor PT) includes channel layers 312 that are similar to the nanostructures 204 discussed above. As shown in FIGS. 6C, 6D, and 6G, the channel layers 312 are suspended over the portions the substrate 308 in the channel regions of the active areas 304. In some embodiments, three channel layers 312 are vertically stacked (or vertically arranged) from each other in the Z-direction for one transistor. However, there may be another appropriate number of nanostructures in one transistor. For example, there may be from 2 to 10 channel layers 312 in one transistor.

The channel layers 312 further extend lengthwise in the X-direction (FIGS. 6C and 6D) and widthwise in the Y-direction (FIG. 6G). In some embodiments, each of the channel layers 312 has a thickness T in the Z-direction, and is in a range from about 3 nm to about 8 nm, as shown in FIG. 6G. As shown in FIG. 6G, in each of the transistors in the transistor cell 302 of the semiconductor structure 300, three channel layers 312 are spaced from each other in the Z-direction by a distance S, which is in a range from about 4 nm to about 15 nm. In some embodiments, the channel layers 312 has vertically a pitch P in the Z-direction and in a range from about 7 nm to about 26 nm.

The channel layers 312 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the channel layers 312 include silicon for the N-type transistor NT. In other embodiments, the channel layers 312 include silicon germanium for the P-type transistor PT. In some embodiments, the channel layers 312 are all made of silicon, and the type of the transistors depend on a work function metal layer wrapping around the channel layers 312. In some embodiments, the channel layers 312 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

As discussed above, the gate structure 306 engages the active areas 304-1 and 304-2 to construct the N-type transistor NT and the P-type transistor PT. The gate structure 306 has a gate dielectric layer 318 and a gate electrode layer 320. As discussed above, the gate structure 306 wraps and/or surrounds each of the channel layers 312 in the channel regions of the active areas 304-1 and 304-2. More specifically, the gate dielectric layer 318 wraps around each of the channel layers 312, and the gate electrodes layer 320 wraps around the gate dielectric layer 318 and the channel layers 312. In some embodiments, the gate structure 306 further includes an interfacial layer (such as having silicon dioxide, silicon oxynitride, or other suitable materials) between the gate dielectric layer 318 and the channel layers 312.

The gate dielectric layer 318 may include oxide with nitrogen doped dielectric material (initial layer) combined with metal content high-K dielectric material (K value (dielectric constant)>13). For example, gate dielectric layer 318 may include hafnium oxide (HfO₂), which has a dielectric constant in a range from about 18 to about 40. Alternatively, the gate dielectric layer 318 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba, Sr)TiO₃ (BST), Al₂O₃, Si₃N₄, oxynitrides (SiON), combinations thereof, or other suitable material. The gate dielectric layer 318 may be formed by chemical oxidation, thermal oxidation, ALD, CVD, and/or other suitable methods.

The gate electrode layer 320 is formed to wrap around the gate dielectric layer 318 and the center portions of the channel layers 312, as shown in FIGS. 6C and 6D. In some embodiments, the gate electrode layer 320 may include an N-type work function metal layer for the N-type transistor NT and/or a P-type work function metal layer for the P-type transistor PT. More specifically, the gate electrode layer 320 may have the N-type work function metal layer between the source/drain features 314N with an N-type dopant for the N-type transistor NT and P-type work function metal layers between the source/drain features 314P with a P-type dopant for the P-type transistor PT, in accordance with some embodiments of the present disclosure.

In an embodiment, the N-type work function metal layer is a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer 320N may be deposited utilizing ALD, CVD, or the like. However, any suitable materials and processes may be utilized to form the N-type work function metal layer 320N.

In an embodiment, the P-type work function metal layer is a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer 320P may be deposited using a deposition process such as ALD, CVD, or the like, although any suitable deposition process may be used.

In some embodiments, the gate electrode layer 320 may include a single layer or alternatively a multi-layer structure. In some embodiments, the gate electrode layer 320 may further include a capping layer, a barrier layer, and a fill material (not shown). The capping layer may be formed adjacent to the gate dielectric layers 318 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent to the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The semiconductor structure 300 further includes gate spacers 322 similar to gate spacers 212 discussed above. More specifically, the gate spacers 322 are on sidewalls of the gate structure 306 and the dielectric structures 316, and over the channel layers 314, as shown in FIGS. 6C and 6D. In some embodiments, the gate spacers 322 are over the channel layers 314 and on top sidewalls of the gate structure 306, and thus are also referred to as gate top spacers or top spacers. Furthermore, the dielectric constant (K value) of the gate spacers 322 is lower than the dielectric constant (K value) of the gate dielectric layers 318. In some embodiments, the thickness of the gate spacers 322 is greater than the thickness of the gate dielectric layers 318.

The gate spacers 322 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 322 may include a single layer or a multi-layer structure.

As shown in FIGS. 6C and 6D, the semiconductor structure 300 further includes inner spacers 324 on the sidewalls of the gate structure 306 and below the topmost channel layers 312 and the gate spacers 322. Furthermore, the inner spacers 324 are laterally between the source/drain features 314N (or 314P) and the gate structure 306 and between the source/drain features 314N (or 314P) and the dielectric structures 316. The inner spacers 324 are also vertically between adjacent channel layers 312 and between the bottommost channel layers 312 and the substrate 308.

The inner spacers 324 may include a dielectric material having higher K value (dielectric constant) than the gate spacers 322 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

In some embodiments, the gate spacers 322 have a thickness in the X-direction in a range from about 3 nm to about 12 nm, and the inner spacers 324 have a thickness in the X-direction in a range from about 2 nm to about 10 nm. In some embodiments, the thickness of the gate spacers 322 in the X-direction and the thickness of the inner spacers 324 in the X-direction are the same. In other embodiments, the thickness of the gate spacers 322 in the X-direction is less than the thickness of the inner spacers 324 in the X-direction due to the gate spacers 322 are trimmed during sequent processes for forming source/drain contacts.

As shown in FIGS. 6A to 6H, the semiconductor structure 300 further includes gate isolation features 326 at ends of the gate structure 306 and the dielectric structures 316. Therefore, the gate isolation features are also referred to as the gate end dielectric structures. In some embodiments, the gate isolation features 326 are on opposite sides of the gate structure 306 and the dielectric structures 316 in the Y-direction, as shown in FIGS. 6A to 6H. Furthermore, the gate isolation features 326 attached to the gate structure 306, the gate spacers 322, and the dielectric structures 316 in the Y-direction, as shown in FIGS. 6A to 6H. The gate isolation features 326 extend lengthwise in the X-direction to separate the transistor cell 302 from other device (e.g., SRAM cells or logic cells) in the Y-direction. In some embodiments, the gate isolation features 326 also separate the gate structure 306 and/or the dielectric structures 316 from gate structures and/or dielectric structures of other transistor cells (not shown) in the semiconductor structure 300. As shown in FIGS. 6E to 6H, the gate isolation features 326 further extend vertically into the isolation feature 310 in the Z-direction. In some embodiments, bottom surfaces of the gate isolation features 326 are lower than the bottom surface of the gate structure 306, as shown in FIG. 6G.

The material of the gate isolation features 326 can be single dielectric layer or multiple layers and selected from a group consisting of Si₃N₄, nitride based dielectric layer, SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, high K material (K>=9), or combinations thereof.

Referring to FIGS. 6C to 6F, the semiconductor structure 300 further includes source/drain features 314N (including source/drain features 314N-1 and 314N-2) and source/drain features 314P (including source/drain features 314P-1 and 314P-2) over the substrate 308 and in the source/drain regions of the active areas 304. As shown in FIGS. 6C and 6D, the source/drain features 314N are disposed on opposite sides of the gate structure 306 and connected by the channel layers 312 in the X-direction to form the N-type transistor NT. Similarly, the source/drain features 314P are disposed on opposite sides of the gate structure 306 and connected by the channel layers 312 in the X-direction to form the P-type transistor PT.

Similar to the source/drain features 214 discussed above, the channel layers 312 extend in the X-direction to connect one source/drain feature 314N/314P to the other source/drain feature 314N/314P. In some aspects, the source/drain features 314N/314P are disposed on opposite sides of the respective channel layers 312 in the X-direction. More specifically, the source/drain features 314N/314P are attached and electrically connected to the channel layers 312 in the X-direction, as shown in FIGS. 6C and 6D. In other words, the channel layers 312 are between and attached to the source/drain features 314N/314P in the X-direction. In some embodiments, a width of each of the source/drain features 314N/314P in the Y-direction is different than a height of each of the source/drain features 314N/314P in the Z-direction, as shown in FIGS. 6E and 6F. The source/drain features 314N/314P may also be referred to as source/drain, or source/drain regions. In some embodiments, source/drain feature(s) may refer to a source or a drain, individually or collectively dependent upon the context.

The source/drain features 314N and 314P may be formed by using an epitaxial growth process. In some embodiments, the source/drain features 314N may include epitaxially-grown material selected from a group consisting of SiP, SiC, SiPC, SiAs, Si, or a combination thereof. In some embodiments, the epitaxially-grown material of the source/drain features 314N may be doped with N-type dopants (such as phosphorus, arsenic, other N-type dopant, or combinations thereof) having a doping concentration in a range from about 2×10¹⁹/cm³ to 3×10²¹/cm³. In some embodiments, the source/drain features 314N for N-type transistors may be respectively referred to as N-type features and N-type source/drain features.

In some embodiments, the source/drain features 314P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 314P may be doped with P-type dopants (such as boron, indium, other P-type dopant, or combinations thereof) having a doping concentration in a range from about 1×10¹⁹/cm³ to 6×10²⁰/cm³. In some embodiments, the source/drain features 314P for P-type transistors may be respectively referred to as P-type source/drain features.

Referring to FIGS. 6C to 6E, the semiconductor structure 300 further includes bottom dielectric layers 328 under the source/drain features 314N-1 and 314P-1 and over the substrate 308. More specifically, the bottom dielectric layers 328 are vertically between the source/drain feature 314N-1 and the substrate 308 and between the source/drain feature 314P-1 and the substrate 308, as shown in FIGS. 6C to 6E. In some embodiment, the bottom dielectric layer 328 is attached to the sidewalls of the inner spacers 324 in the X-direction, as shown in FIGS. 6C and 6D, and attached to the sidewalls of the isolation feature 310 in the Y-direction, as shown in FIG. 6E. In some aspect, the bottom dielectric layer 328 is attached to and between the inner spacers 324 in the X-direction.

In some embodiments, the dielectric material of the bottom dielectric layers 328 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the source/drain features 314N-1 and 314P-1 are separated from the substrate 308 by the bottom dielectric layers 328. As such, it prevents the leakage current of the resultant transistors through the substrate 308, thereby improving performances of the resultant transistors.

Referring to FIGS. 6A and 6C to 6E, the semiconductor structure 300 further includes a source/drain contact 330. The source/drain contact 330 is over and electrically connected to the source/drain feature 314N-1 of the N-type transistor NT and the source/drain feature 314P-1 of the P-type transistor PT. The source/drain contact 330 extends lengthwise the Y-direction, as shown in FIGS. 6A and 6E. In some embodiments, a top surface of the source/drain contact 330 is substantially level with the top surface of the gate structure 306, as shown in FIGS. 6C and 6D. The source/drain contact 330 is over the source/drain features 314N-1 and 314P-1, such that the source/drain contact 330 may be referred to as the frontside source/drain contact.

As shown in FIGS. 6C to 6E, in the X-Z and Y-Z cross-sectional views, a portion of the source/drain contact 330 extends into the source/drain feature 314N-1 or 314P-1. More specifically, the source/drain contact 330 has a first portion 330r extending away from the source/drain feature 314N-1 or 314P-1 and second portions 330t extending into the source/drain feature 314N-1 or 314P-1, as shown in FIGS. 6C to 6E. Therefore, the second portion 330 t of the source/drain contact 330 is surrounded by the source/drain feature 314N-1 or 314P-1. The second portions 330t are under the first portion 330r. Furthermore, bottom surfaces of the source/drain contact 330 are lower than bottom surfaces of topmost channel layers 312, as shown in FIGS. 6C and 6D. In other words, bottom surfaces of the second portions 330t of the source/drain contact 330 are lower than the bottom surfaces of topmost channel layers 312. In some embodiments, the first portion 330r is wider than the second portion 330t. In some embodiments, the second portion 330t has slope sidewalls extending in the source/drain feature 314N-1 or 314P-1. In some embodiments, the width of the second portion 330t gradually decreases from its top portion to its bottom portion. In some embodiments, the top width of the second portion 330t is greater than the bottom width of the second portion 330t. It is noted that although the first portion 330r and the second portion 330t are described as two portions, there are no real interface therebetween.

The source/drain contact 330 may include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contact 330 may include single conductive material layer or multiple conductive layers.

Referring to FIGS. 6C to 6E, the semiconductor structure 300 further includes interposing layer 332 on sidewalls of the source/drain contact 330 and over the source/drain features 314N-1 and 314P-1. More specifically, the interposing layer 332 is on sidewalls of the first portion 330r of the source/drain contact 330. In some aspects, the interposing layer 332 surrounds the sidewalls of the first portion 330r of the source/drain contact 330, as shown in FIGS. 6C to 6E. In some embodiment, the interposing layer 332 is the nitrogen content dielectric layer. In some embodiment, the interposing layers 332 is the nitrogen containing oxide layer, such as SiON or SiOCN. Therefore, the interposing layers 332 have lower dielectric constant (k value) than nitride layer (e.g., silicon nitride) for protecting the ILD layer 338 in the formation of the silicide layers 334 with low parasitic capacitance. As shown in FIGS. 6C and 6D, the interposing layer 332 is between and attached to the source/drain contact 330 and the gate spacers 322 in the X-direction to improve the isolation margin for the source/drain contact 330 to the gate structure 306.

Referring to FIGS. 6C to 6E, the semiconductor structure 300 further includes silicide layers 334 over and attached to the source/drain features 314N-1 and 314P-1, and under the and attached to the source/drain contact 330. More specifically, the silicide layers 334 are between the source/drain contact 330 and the source/drain feature 314N-1/314P-1. The silicide layers 334 are on sidewalls of the second portions 330t of the source/drain contact 330. In some aspects, the silicide layers 334 surround the sidewalls of the second portions 330t of the source/drain contact 330, as shown in FIGS. 6C to 6E. In some embodiments, bottom surfaces of the silicide layers 334 are lower than the bottom surfaces of the topmost channel layers 312, as shown in FIGS. 6C and 6D.

The silicide layers 334 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the silicide layer 334 over the source/drain feature 314N-1 and the silicide layer 334 over the source/drain feature 314P-1 have different material. For example, the silicide layer 334 over the source/drain feature 314N-1 include TiSi and the silicide layer 334 over the source/drain feature 314P-1 include silicide material selected from a group consist of PtSi, NiSi, CoSi, or MoSi.

Referring to FIGS. 6C to 6H, the semiconductor structure 300 further includes a gate top dielectric layer 336 over the gate dielectric layer 318, the gate electrode layer 320, the channel layers 312, the dielectric structures 316, and the gate spacers 322. The gate top dielectric layer 336 is used for contact etch protection layer. The material of gate top dielectric layer 336 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

Referring to FIGS. 6C to 6F, the semiconductor structure 300 further includes an inter-layer dielectric (ILD) layer 338. The ILD layer 338 are formed over the isolation feature 310, as shown in FIGS. 6E and 6F. In some embodiments, the ILD layer 338 surrounds the source/drain contact 330. In some embodiments, the ILD layer 338 also fills the spaces between the source/drain features 314N/314P, such that the ILD layer 338 also surrounds the source/drain features 412N/412P.

The semiconductor structure 300 further includes a frontside interconnection structure including an ILD layer 340, an inter-metal dielectric (IMD) layer 342, a gate via VG, a via VD, and metal conductors M1-1 to M1-6. The ILD layer 340 is over the substrate 308, the isolation feature 310, the gate structure 306, the dielectric structures 316, the gate isolation features 326, the source/drain contact 330, and the gate top dielectric layer 336. The IMD layer 342 is over the ILD layer 340, the gate structure 306, the dielectric structures 316, the gate isolation features 326, the source/drain contact 330, and the gate top dielectric layer 336.

The gate via VG and the via VD are disposed in the ILD layer 340 and the metal conductors M1-1 to M1-6 are disposed in the IMD layer 342. The metal conductors M1-1 to M1-6 are over and electrically connected to respective gate structure and respective source/drain contact. The gate via VG is over and attached to the gate structure 306 and electrically connects the gate structure 306 to the metal conductor M1-4. The via VD is over and attached to the source/drain contact 330 and electrically connects the source/drain contact 330 to the metal conductor M1-2.

As shown in FIGS. 6A to 6H, the metal conductors M1-1 to M1-6 extend lengthwise in the X-direction. Furthermore, the metal conductors M1-1 and M1-6 are over and overlap the gate isolation features 326, as shown in FIGS. 6A to 6H. In some embodiments, a width of the metal conductors M1 and M1-6 in the Y-direction is greater than a width of the metal conductors M1-2 to M1-5 in the Y-direction. In some embodiments, the ILD layer 340, the IMD layer 342, the gate via VG, the via VD, and the metal conductors M1-1 to M1-6 may also be referred to as the frontside ILD layer, the frontside IMD layer, the frontside gate via, the frontside vias, and the frontside metal conductors, respectively.

The materials of the gate via VG, the via VD, and the metal conductors M1-1 to M1-6 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

Referring to FIGS. 6B, 6C, 6D, and 6F, the semiconductor structure 300 further includes source/drain contacts 344-1 and 344-2 (may be collectively referred to as the source/drain contacts 344) passing through the substrate 308 and an IMD layer 350 under and attached to the substrate 308. The source/drain contacts 344-1 and 344-2 are respectively under and electrically connected to the source/drain feature 314N-2 of the N-type transistor NT and the source/drain feature 314P-2 of the P-type transistor PT. The source/drain contacts 344 are under the source/drain features 314N-2 and 314P-2, such that the source/drain contacts 344 may be referred to as the backside source/drain contacts.

As shown in FIGS. 6C to 6F, in the X-Z and Y-Z cross-sectional views, portions of the source/drain contacts 344 each extend into the source/drain features 314N-2 or 314P-2. More specifically, each of the source/drain contacts 344 has a first portion 344r extending away from the source/drain feature 314N-2 or 314P-2 and a second portion 344t extending into the source/drain feature 314N-2 or 314P-2, as shown in FIGS. 6C to 6F. Therefore, each of the second portions 344t of the source/drain contacts 344 is surrounded by the source/drain feature 314N-2 or 314P-2. The second portions 344t are over the first portions 344r. Furthermore, top surfaces of the source/drain contacts 344 are higher than top surfaces of bottommost channel layers 312, as shown in FIGS. 6C and 6D. In other words, top surfaces of the second portions 344t of the source/drain contacts 344 are higher than the top surfaces of bottommost channel layers 312. In some embodiments, the first portion 344r is wider than the second portion 344t. In some embodiments, the second portion 344t has slope sidewalls extending in the source/drain feature 314N-2 or 314P-2. In some embodiments, the width of the second portion 344t gradually decreases from its bottom portion to its top portion. In some embodiments, the bottom width of the second portion 344t is greater than the top width of the second portion 344t. It is noted that although the first portion 344r and the second portion 344t are described as two portions, there are no real interface therebetween.

The source/drain contacts 344 may include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 344 may include single conductive material layer or multiple conductive layers.

Referring to FIGS. 6C to 6F, the semiconductor structure 300 further includes interposing layers 346 on sidewalls of the source/drain contacts 344 and under the source/drain features 314N-2 and 314P-2. More specifically, the interposing layers 346 are on sidewalls of the first portions 344r of the source/drain contacts 344. In some aspects, the interposing layers 346 surround the sidewalls of the first portions 344r of the source/drain contacts 344, as shown in FIGS. 6C to 6F. In some embodiment, the interposing layers 346 is the nitrogen content dielectric layer. In some embodiment, the interposing layers 346 is the nitrogen containing oxide layer, such as SiON or SiOCN. Therefore, the interposing layers 346 have lower dielectric constant (k value) than nitride layer (e.g., silicon nitride) for protecting the substrate 308 in the formation of the silicide layers 348 with low parasitic capacitance. As shown in FIGS. 6C and 6D, the interposing layers 346 are between and attached to the source/drain contacts 344 and the substrate 308 in the X-direction and between and attached to the source/drain contacts 344 and the IMD layer 350 in the X-direction to improve the isolation margin for the source/drain contacts 344.

Furthermore, as shown in FIGS. 6C to 6F, top surfaces of the interposing layers 346 on the sidewalls of the first portions 344r of the source/drain contacts 344 are higher than the bottom surface of the gate structure 306. In some embodiments, the top surfaces of the interposing layers 346 are substantially level with top surfaces of the bottom dielectric layers 328. This is due to the bottom dielectric layers under the source/drain features 314N-2 and 314P-2 are removed for the formation of the source/drain contacts 344. Therefore, as shown in FIGS. 6C to 6F, the interposing layers 346 are also between and attached to the source/drain contacts 344 and the inner spacers 324.

Referring to FIGS. 6C to 6E, the semiconductor structure 300 further includes silicide layers 348 under and attached to the source/drain features 314N-2 and 314P-2, and over the and attached to the source/drain contacts 344. More specifically, the silicide layers 348 are between the source/drain contact 344-1/344-2 and the source/drain feature 314N-2/314P-2. The silicide layers 348 are on sidewalls of the second portions 344t of the source/drain contacts 344. In some aspects, the silicide layers 348 surround the sidewalls of the second portions 344t of the source/drain contacts 344, as shown in FIGS. 6C to 6F. In some embodiments, top surfaces of the silicide layers 348 are higher than the top surfaces of the bottommost channel layers 312, as shown in FIGS. 6C and 6D.

The silicide layers 348 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the silicide layer 348 under the source/drain feature 314N-2 and the silicide layer 348 under the source/drain feature 314P-2 have different material. For example, the silicide layer 348 under the source/drain feature 314N-2 include TiSi and the silicide layer 348 under the source/drain feature 314P-2 include silicide material selected from a group consist of PtSi, NiSi, CoSi, or MoSi.

The conductivity of the silicide layers 334 and 348 is greater than the conductivity of the source/drain features 314N/314P. In some embodiments, the conductivity of the source/drain contacts 330 and 344 is greater than the conductivities of the silicide layers 334 and 348 and the source/drain features 314N/314P.

The semiconductor structure 300 further includes a backside interconnection structure including an IMD layer 352 and metal conductors BM1-1 and BM1-2. The IMD layer 352 is under the substrate 308, the isolation feature 310, the gate structure 306, the dielectric structures 316, the gate isolation features 326, the source/drain contacts 344, and the IMD layer 350.

The metal conductors BM1-1 and BM1-2 are disposed in the IMD layer 352. As shown in FIGS. 6B to 6F, the metal conductors BM1-1 and BM1-2 are under and electrically connected to respective source/drain contact. More specifically, the metal conductor BM1-1 is under and electrically connected to the source/drain contact 344-1 and the metal conductor BM1-2 is under and electrically connected to the source/drain contact 344-2.

As shown in FIGS. 6A to 6H, the metal conductors BM1-1 and BM1-2 extend lengthwise in the X-direction. In some embodiments, a width of the metal conductors BM1-1 and BM1-2 in the Y-direction is greater than a width of the metal conductors M1-1 to M1-6 in the Y-direction. In some embodiments, the IMD layers 350 and 352 and the metal conductors BM1-1 and BM1-2 may also be referred to as the backside IMD layers and the backside metal conductors, respectively.

The metal conductor BM1-1 serves as VSS line that is electrically coupled to a voltage source (not shown) (e.g., a supply voltage VSS (or ground)) and electrically connected to the transistor cell 302 to supply VSS voltage (or ground voltage) to the transistor cell 302. More specifically, the metal conductor BM1-1 is under and electrically connected to the source/drain feature 314N-2 of the N-type transistor NT through the source/drain contact 344-1 and the silicide layer 348, as shown in FIGS. 6A to 6F. Therefore, VSS voltage (or ground voltage) is supplied to the source/drain feature 314N-2 of the N-type transistor NT. In some embodiments, the metal conductor BM1-1 may be referred to as the (back-side) VSS conductor, the (back-side) VSS line, the (back-side) power conductor, or the (back-side) power line.

The metal conductor BM1-2 serves as VDD line that is electrically coupled to a voltage source (not shown) (e.g., a supply voltage VDD) and electrically connected to the transistor cell 302 to supply VDD voltage to the transistor cell 302. More specifically, the metal conductor BM1-2 is under and electrically connected to the source/drain feature 314P-2 of the P-type transistor PT through the source/drain contact 344-2 and the silicide layer 348, as shown in FIGS. 6A to 6F. Therefore, VDD voltage is supplied to the source/drain feature 314P-2 of the P-type transistor PT. In some embodiments, the metal conductor BM1-2 may be referred to as the (back-side) VDD conductor, the (back-side) VDD line, the (back-side) power conductor, or the (back-side) power line.

The materials of the metal conductors BM1-1 and BM1-2 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

The ILD layers 338 and 340 and the IMD layers 342, 350, and 352 include a dielectric material including, for example, silicon oxide, silicon nitride, silicon oxynitride, tetraethylorthosilicate (TEOS) formed oxide, phosphosilicate glass (PSG), boron doped silicon glass (BSG), borophosphosilicate glass (BPSG), fluoride-doped silica glass (FSG), low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some embodiments, the ILD layers 338 and 340 and the IMD layers 342, 350, and 352 are a dielectric layer that includes a low-k dielectric material (generally referred to as a low-k dielectric layer). The ILD layers 338 and 340 and the IMD layers 342, 350, and 352 may include a multilayer structure having multiple dielectric materials.

Generally, interconnection of devices and transistor cells are disposed over or at frontside of transistors to form desired circuit routing. As transistors and transistor cells continue to be scaled down, space for interconnection routing is also decreased. In order to achieve desired circuit routing, metal conductor width and conductor-to-conductor space are decreased, thereby increasing resistance and parasitic capacitance to impact performance of devices and transistor cells. In some embodiments of present disclosure, a part of interconnection of devices and transistor cells is disposed under or at backside of transistors to improve upon the above issue.

The metal conductors BM1-1 and BM1-2 serving as VSS line and VDD line are disposed at the backside of the transistor cell 302, such that the crowded space at the front-side interconnection structure is relieved to reduce the routing complexity of the transistor cell 302. Therefore, the metal conductors M1-1 to M1-6 used for connections of the transistor cell 302 may be designed with wider width in the Y-direction, thereby reducing the circuit resistance. The space at the backside of the transistor cell 302 is completely used for the metal conductors BM1-1 and BM1-2, so that the metal conductors BM1-1 and BM1-2 may have the widest width in the Y-direction, thereby having lowest metal resistance in the semiconductor structure 300. As such, the performance of transistor cell 302 is improved.

Furthermore, as discussed above, the source/drain contacts 330 and 344 extending deep into the source/drain features 314N/314P, such that the current crowding and source/drain resistance are reduced, thereby improving the performance of transistor cell 302.

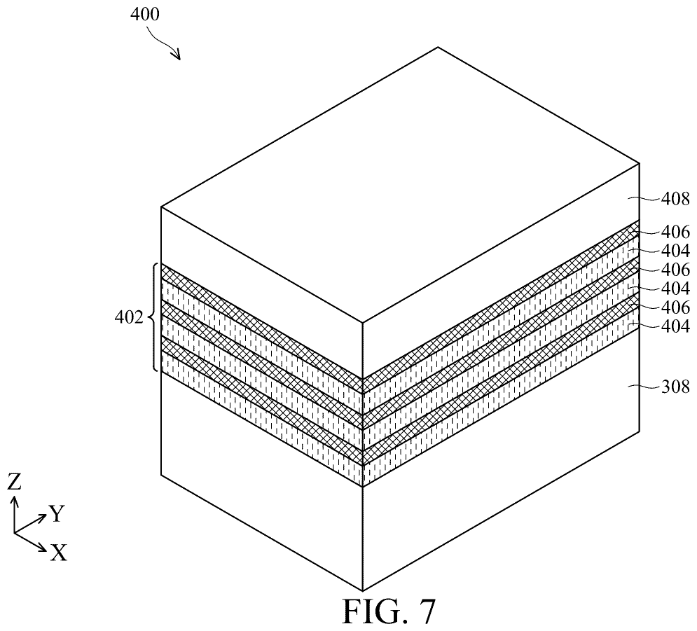

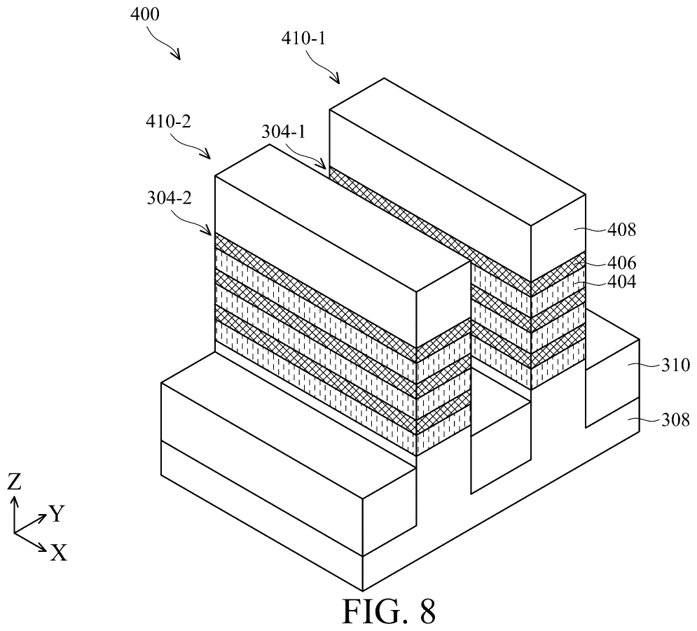

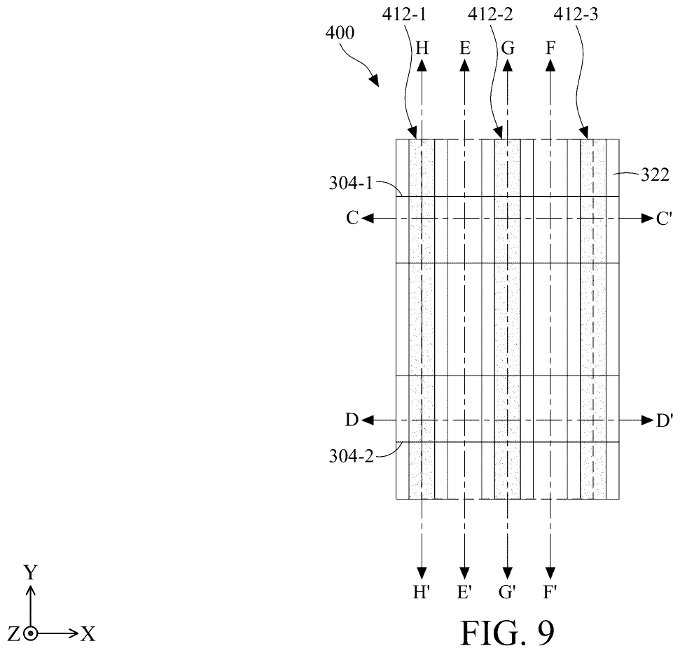

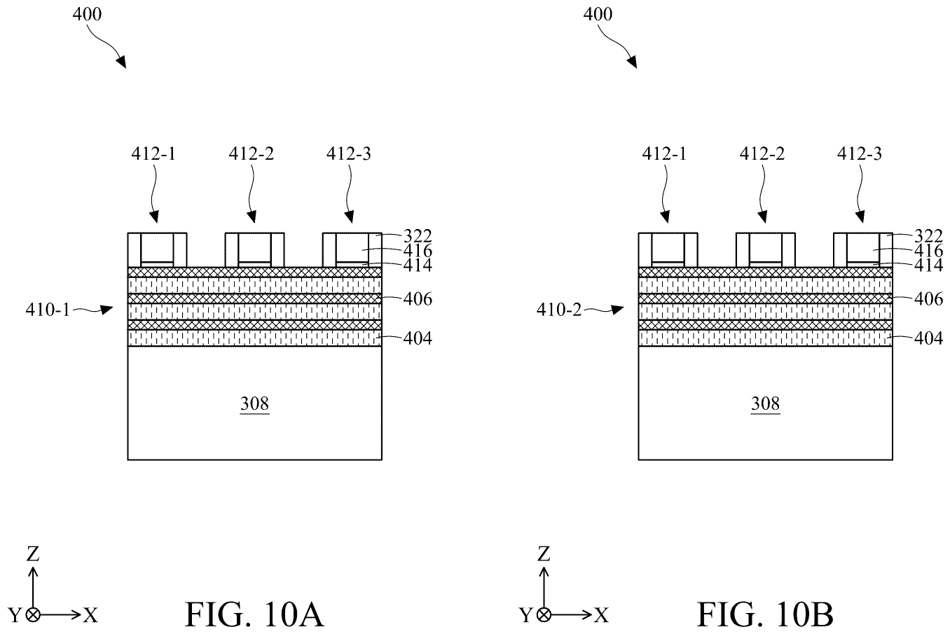

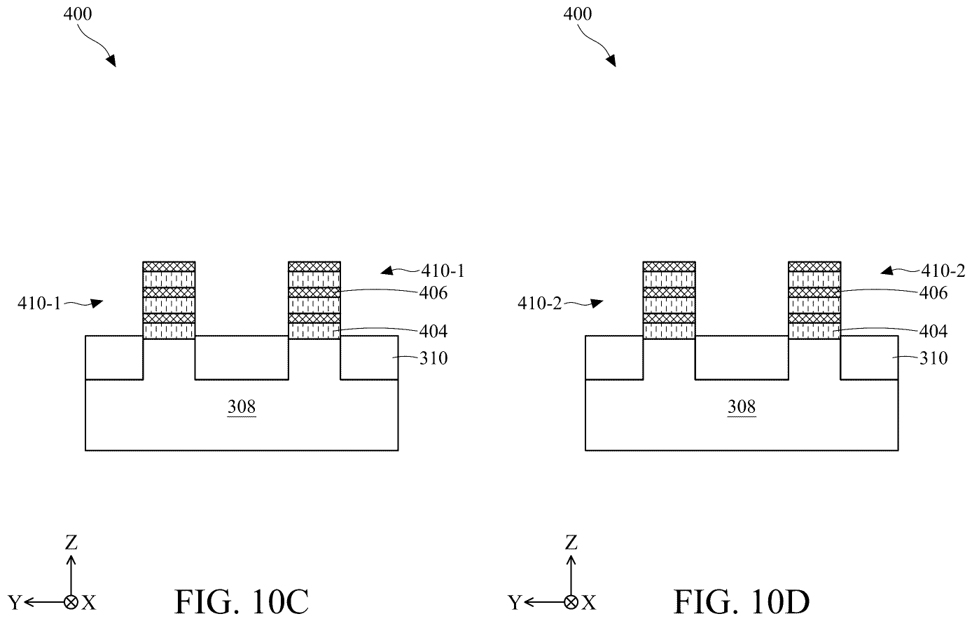

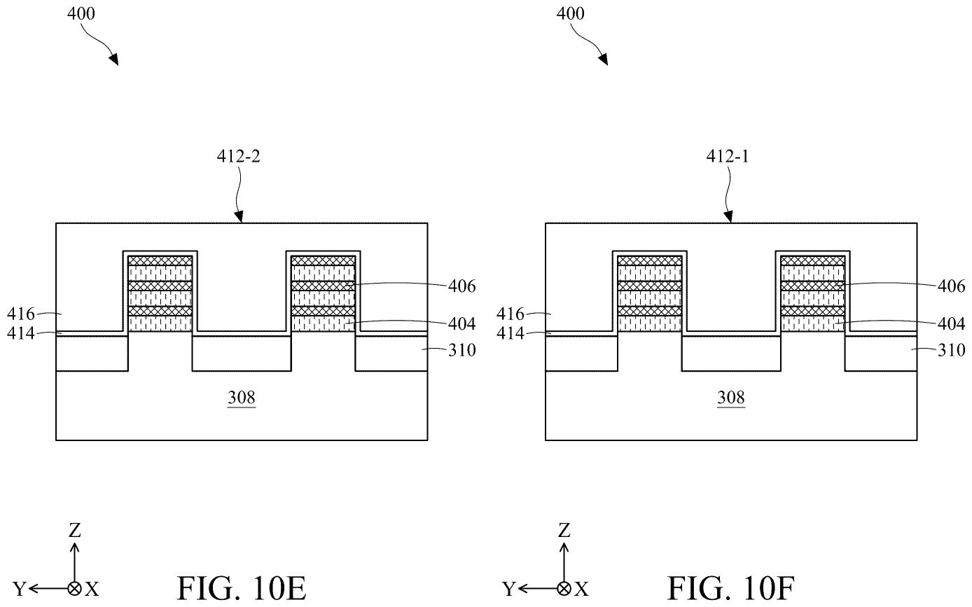

FIGS. 7 and 8 illustrate perspective views of a workpiece 400 at various fabrication stages for the semiconductor structure 300, in accordance with some embodiments of the present disclosure. FIGS. 9, 13, and 17 illustrate top views (or layouts) of the workpiece 400 at various fabrication stages for the semiconductor device 300, in accordance with some embodiments of the present disclosure. FIGS. 10A, 11A, 12A, 14A, 15A, 16A, 18A, 19A, 20A, 10B, 11B, 12B, 14B, 15B, 16B, 18B, 19B, and 20B illustrate X-Z cross-sectional views of the workpiece 400 at various fabrication stages for the semiconductor structure 300 along lines C-C′ and D-D′ of FIGS. 9, 13, and 17, respectively, in accordance with some embodiments of the present disclosure. FIGS. 10C, 11C, 12C, 14C, 15C, 16C, 18C, 19C, 20C, 10D, 11D, 12D, 14D, 15D, 16D, 18D, 19D, 20D, 10E, 11E, 12E, 14E, 15E, 16E, 18E, 19E, 20E, 10F, 11F, 12F, 14F, 15F, 16F, 18F, 19F, and 20F illustrate Y-Z cross-sectional views of the workpiece 400 at various fabrication stages for the semiconductor structure 300 along lines E-E′, F-F′, G-G′, and H-H′ of FIGS. 9, 13, and 17, respectively, in accordance with some embodiments of the present disclosure.

Referring to FIG. 7, a workpiece 400 is provided. As shown in FIG. 7, the workpiece 400 includes the substrate 308 discussed above and a stack 104 over the substrate 308. The stack 402 includes semiconductor layers 404 and 406, and the semiconductor layers 404 and 406 are alternatingly stacked in the Z-direction. The semiconductor layers 404 and the semiconductor layers 406 may have different semiconductor compositions. In some embodiments, semiconductor layers 404 are formed of silicon germanium (SiGe) and the semiconductor layers 406 are formed of silicon (Si). In these embodiments, the additional germanium content in the semiconductor layers 404 allow selective removal or recess of the semiconductor layers 404 without substantial damages to the semiconductor layers 406, so that the semiconductor layers 404 are also referred to as sacrificial layers. In some embodiments, the semiconductor layers 404 and 406 are epitaxially grown over (on) the substrate 308 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

The semiconductor layers 404 and the semiconductor layers 406 are deposited alternatingly, one-after-another, to form the stack 402. It should be noted that three (3) layers of the semiconductor layers 404 and three (3) layers of the semiconductor layers 406 are alternately and vertically arranged (or stacked) as shown in FIG. 7, which are for illustrative purposes only and not intended to be limiting beyond what is specifically recited in the claims. The number of layers depends on the desired number of channel layers for the semiconductor device. In some embodiments, there may be from 2 to 10 semiconductor layers 404 alternating with 2 to 10 semiconductor layers 406 in the stack 402.

For patterning purposes, the workpiece 400 may also include a hard mask layer 408 over the stack 402. The hard mask layer 408 may be a single layer or a multi-layer. In some embodiments, the hard mask layer 408 is a single layer and includes a silicon germanium layer. In some embodiments, the hard mask layer 408 is a multi-layer and includes a silicon nitride layer and a silicon oxide layer over the silicon nitride layer. In some other embodiments, the hard mask layer 408 is a multi-layer and includes a silicon germanium layer and a silicon layer over the silicon germanium layer.

Referring to FIG. 8, after the formation of the stack 402, the active areas 342-1 and 304-2 discussed above are defined on the workpiece 400 for patterning the stack 402 to form fins 410-1 and 410-2 (may be collectively referred to as the fins 410) over the substrate 308. As shown in FIG. 8, the fins 410-1 and 410-2 extend lengthwise in the X-direction. Each of the fins 410-1 and 410-2 includes semiconductor layers 404 and 406 alternating stacked in the Z-direction.

The fins 410 may be patterned using suitable processes including double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fins 410 by etching the stack 402 and the substrate 308. The etching process may include dry etching, wet etching, reactive ion etching (RIE), and/or other suitable processes.

Still referring to FIG. 8, after the definition of the active areas 304 and the formation of the fins 410, the isolation feature 310 discussed above is formed over the substrate 308. The isolation feature 310 is formed between the active areas 304, as discussed above. In some embodiments, the top surface of the isolation feature 310 is lower than the top surface of the fin base under the semiconductor layers 404 and 406. In some embodiments, a dielectric material for the isolation feature 310 is first deposited over the substrate 308. Specifically, the dielectric material is deposited and formed over the fins 410 and the substrate 308 to cover the fins 410 and the substrate 308. In some aspects, the dielectric material is formed to wrap around the fins 410. The deposited dielectric material is then thinned and planarized, for example by a chemical mechanical polishing (CMP) process. The hard mask layer 408 is also removed during the CMP process. The planarized dielectric material is further recessed by a dry etching process, a wet etching process, and/or a combination thereof to form the isolation feature 310. In some embodiments, before the formation of the isolation feature 310, a liner layer may be conformally deposited over the substrate 308 using ALD or CVD.

Referring to FIGS. 9 and 10A to 10F, dummy gate structures 412-1 to 412-3 (may be collectively referred to as the dummy gate structures 412) are formed over the fins 410. The dummy gate structures 412 extend in the Y-direction, as shown in FIGS. 9, 10E, and 10F. In some embodiments, to form the dummy gate structures 412, a dummy interfacial material for dummy interfacial layers 414 is first formed over fins 410. In some embodiments, the dummy interfacial layer 414 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material for dummy gate electrodes 416 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate material and/or the dummy interfacial material may be formed by way of a thermal oxidation process and/or a deposition process (e.g., physical vapor deposition (PVD), CVD, PECVD, and ALD).

After the formation of the dummy interfacial material and the dummy gate material, one or more etching processes may be performed to pattern the dummy gate material for the dummy gate electrodes 416 and the dummy interfacial material for the dummy interfacial layers 414, thereby forming the dummy gate structures 412 each having the dummy interfacial layer 414 and the dummy gate electrode 416. The dummy interfacial layers 414 may also be referred to as dummy gate dielectrics. The dummy gate structures 412 may undergo a gate replacement process through subsequent processing to form metal gates, such as a high-k metal gate, as discussed in greater detail below.

Still referring to FIGS. 9 and 10A to 10F, after the formation of the dummy gate structures 412, the gate spacers 322 discussed above are formed on sidewalls of the dummy gate structures 412 and over the top surfaces of the fins 410. More specifically, the gate spacers 322 are formed on opposite sidewalls of the dummy gate structures 412. In some embodiments, the gate spacers 322 may be formed by conformally depositing a spacer layer (containing the dielectric material) over the fins 410 and dummy gate structures 412, followed by an anisotropic etching process to remove top portions of the spacer layer from the top surfaces of the fins 410 and dummy gate structures 412. After the etching process, portions of the spacer layer on the sidewall surfaces of the fins 410 and the dummy gate structures 412 substantially remain and become the gate spacers 322. In some embodiments, the anisotropic etching process is a dry (e.g., plasma) etching process. Additionally or alternatively, the formation of the gate spacers 322 may also involve chemical oxidation, thermal oxidation, ALD, CVD, and/or other suitable methods. The gate spacers 322 may also be interchangeably referred to as top spacers.

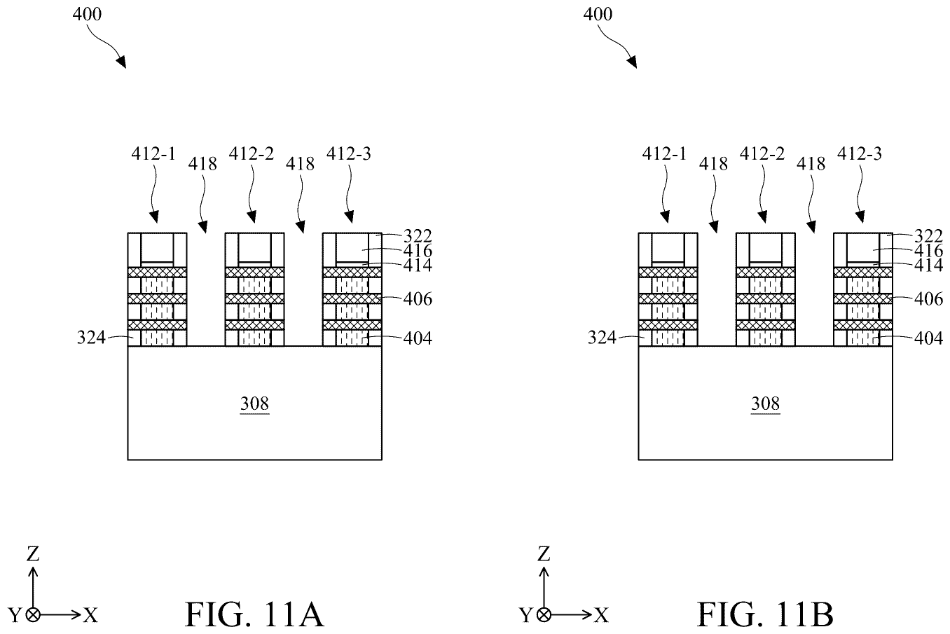

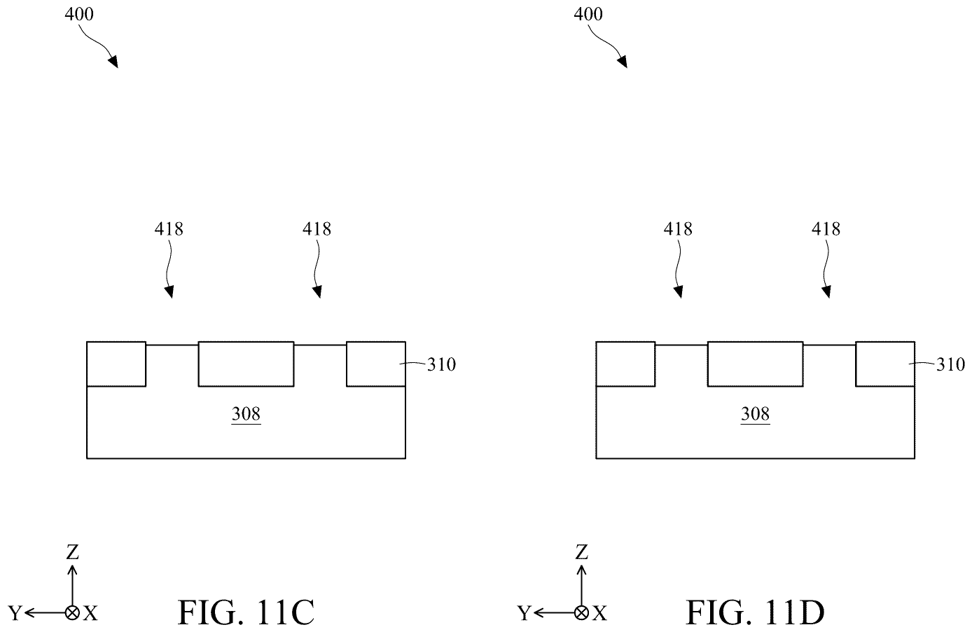

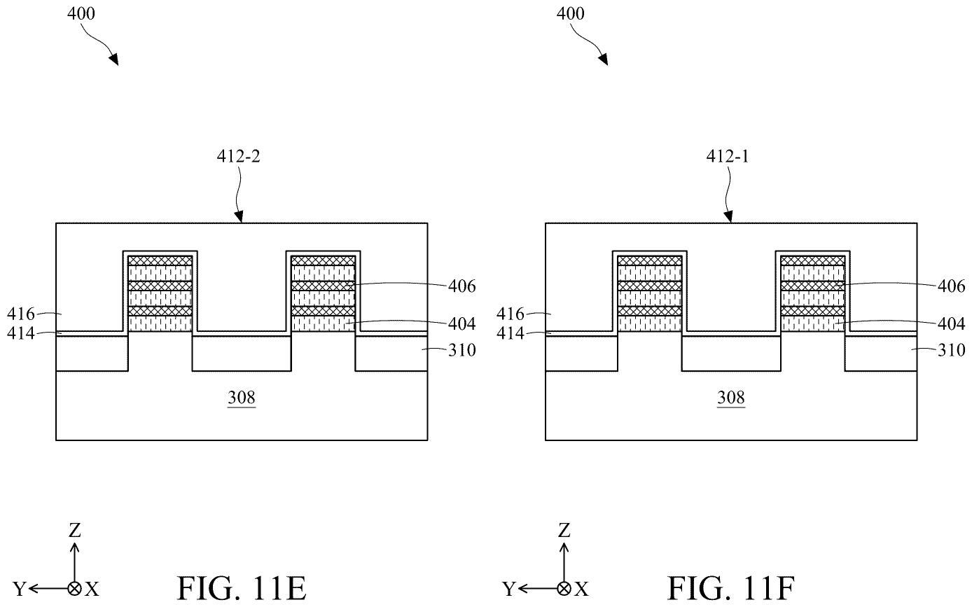

Referring to FIGS. 9 and 11A to 11F, after the formation of the gate spacers 322, the fins 410 are recessed to form source/drain trenches 418 in the fins 410 (or passing through the semiconductor layers 404 and 406). More specifically, the source/drain trenches 418 are formed on opposite sides of the dummy gate structures 412 and in the fins 410. The source/drain trenches 418 may be formed by performing one or more etching processes to remove portions of the semiconductor layers 404, the semiconductor layers 406 that do not vertically overlap or be covered by the dummy gate structures 412 and the gate spacers 322. In some embodiments, a single etchant may be used to remove the semiconductor layers 404 and the semiconductor layers 406, whereas in other embodiments, multiple etchants may be used to perform the etching process.

Still referring to FIGS. 9 and 11A to 11F, after the formation of the source/drain trenches 418, the inner spacers 324 discussed above are formed under the gate spacers 322 and between the semiconductor layers 406 as well as between the semiconductor layers 406 and the substrate 308. In formation of the inner spacers 324, side portions of the semiconductor layers 404 are removed via a selective etching process. Specifically, the selective etching process is performed that selectively etches the side portions of the semiconductor layers 404 under the gate spacers 322 through the source/drain trenches 418, with minimal (or no) etching of semiconductor layers 406, such that gaps are formed between the semiconductor layers 406 as well as between the semiconductor layers 406 and the substrate 308. The etching process is configured to laterally etch (e.g., in the first direction) the semiconductor layers 404 below the gate spacers 322. The selective etching process is a dry etching process, a wet etching process, another suitable etching process, or a combination thereof.

After the formation of the gaps between the semiconductor layers 406 as well as between the semiconductor layers 406 and the substrate 308, the inner spacers 324 are then formed to fill the gaps. In some embodiments, sidewalls of the inner spacers 324 are aligned to sidewalls of the gate spacers 322 and the semiconductor layers 406, as shown in FIGS. 11A and 11B. In order to form the inner spacers 324, a deposition process forms a spacer layer into the source/drain trenches 418 and the gaps, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 416. The deposition process is configured to ensure that the spacer layer fills the gaps between the semiconductor layers 406 as well as between the semiconductor layer 406 and the substrate 308 under the gate spacers 322. An etching process is then performed that selectively etches the spacer layer to form inner spacers 324 (as shown in FIGS. 11A and 11B) with minimal (to no) etching of the semiconductor layer 406, the substrate 308, the dummy gate structures 412, and the gate spacers 322.

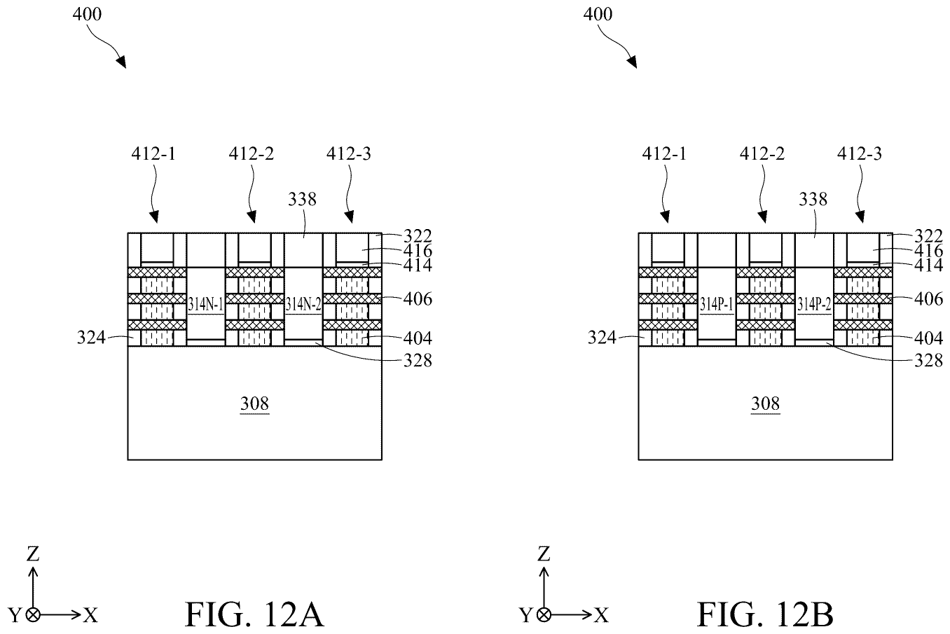

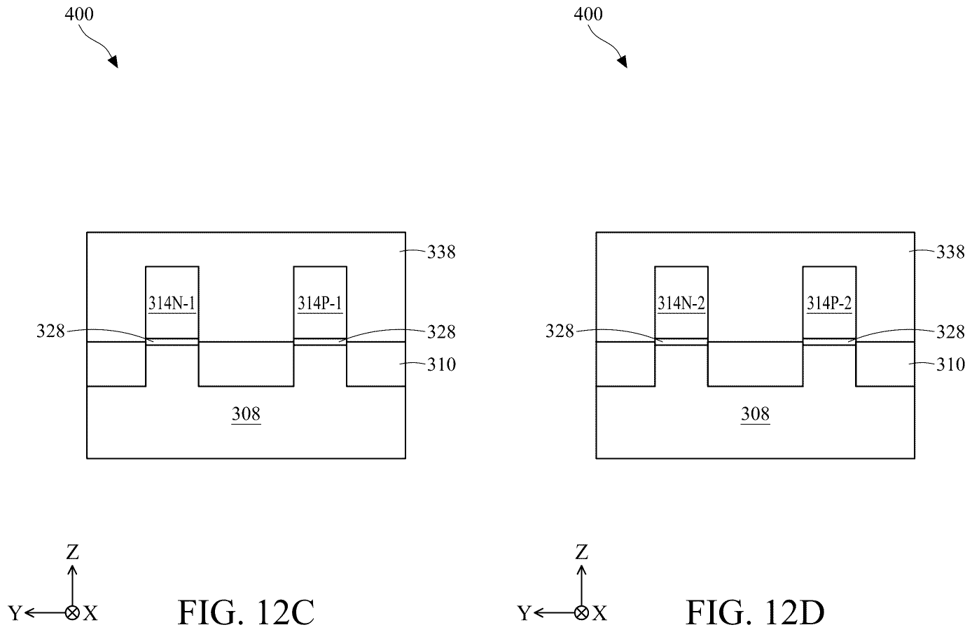

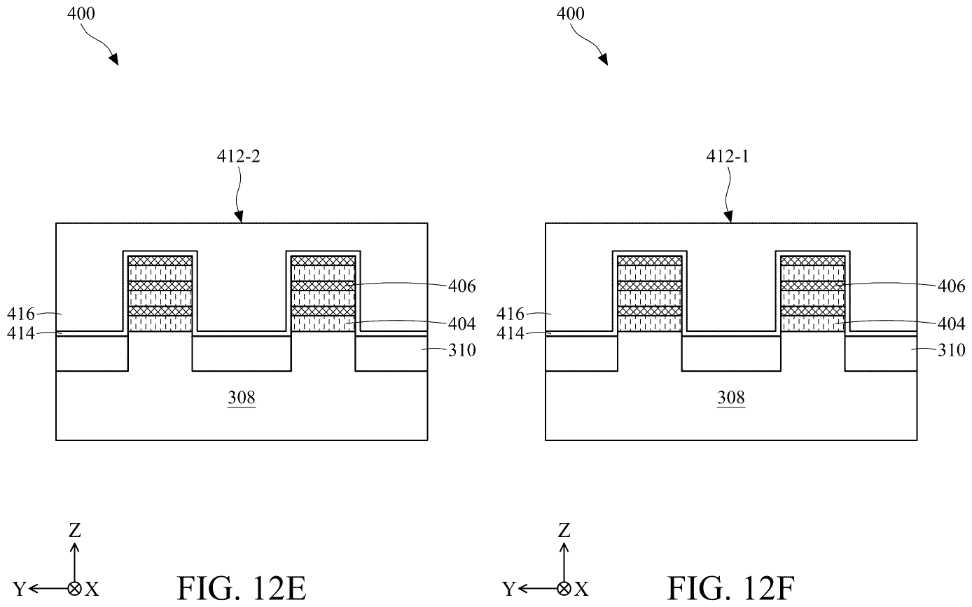

Referring to FIGS. 9 and 12A to 12F, after the formation of the inner spacers 324, the bottom dielectric layers 328 and the source/drain features 314N/314P over the bottom dielectric layers 328 discussed above are formed in the source/drain trenches 418. One or more epitaxy processes may be employed to grow the source/drain features 314N/314P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. One or more annealing processes may be performed to activate the dopants in the source/drain features 314N/314P. The annealing processes may include rapid thermal annealing (RTA) and/or laser annealing processes.

Still referring to FIGS. 9 and 12A to 12F, after the formation of the bottom dielectric layers 328 and the source/drain features 314N/314P, the ILD layer 338 discussed above is formed over the isolation feature 310, the source/drain features 314N/314P to fill the spaces between the gate spacers 322 and between the source/drain features 314N/314P to surround the source/drain features 314N/314P. The ILD layer 338 is also formed over the dummy gate structures 412. Subsequent to the formation of the ILD layer 338, a CMP process and/or other planarization process is performed on the ILD layer 338 until the top surfaces of the dummy gate structures 410 are exposed.

In some embodiments, before the formation of the ILD layer 338, a contact etch stop layer (CESL) may be conformally formed on the sidewalls of the gate spacers 322 and over the top surfaces of the source/drain features 314N/314P. The ILD layer 338 is then formed over and between the CESL to fill the space between the CESL. The CESL includes a material that is different than the ILD layer 338. The CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods.

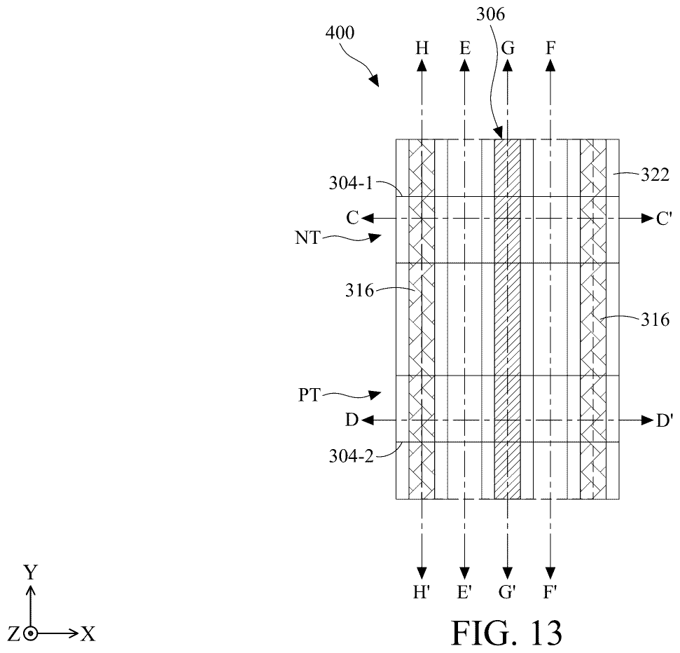

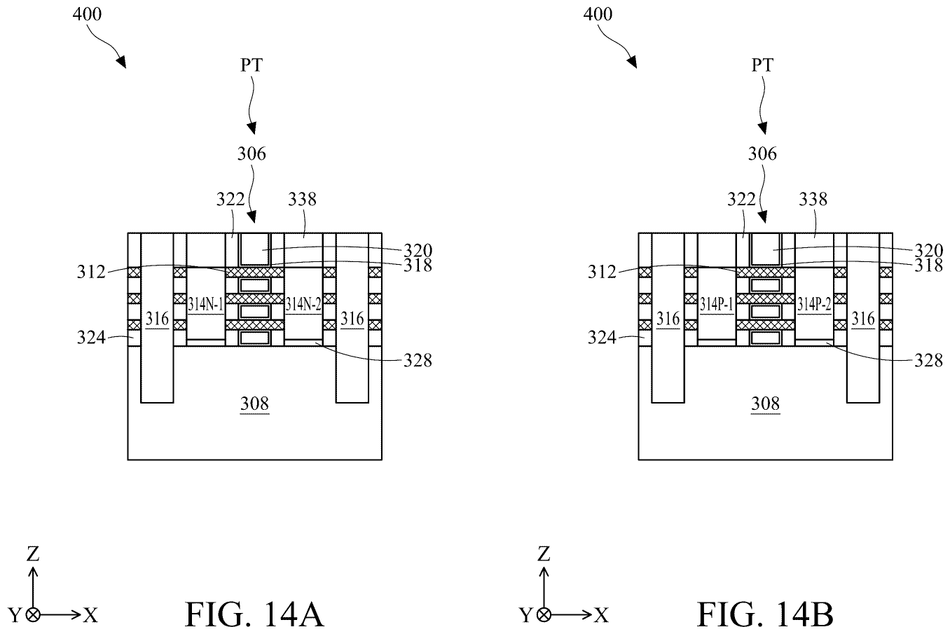

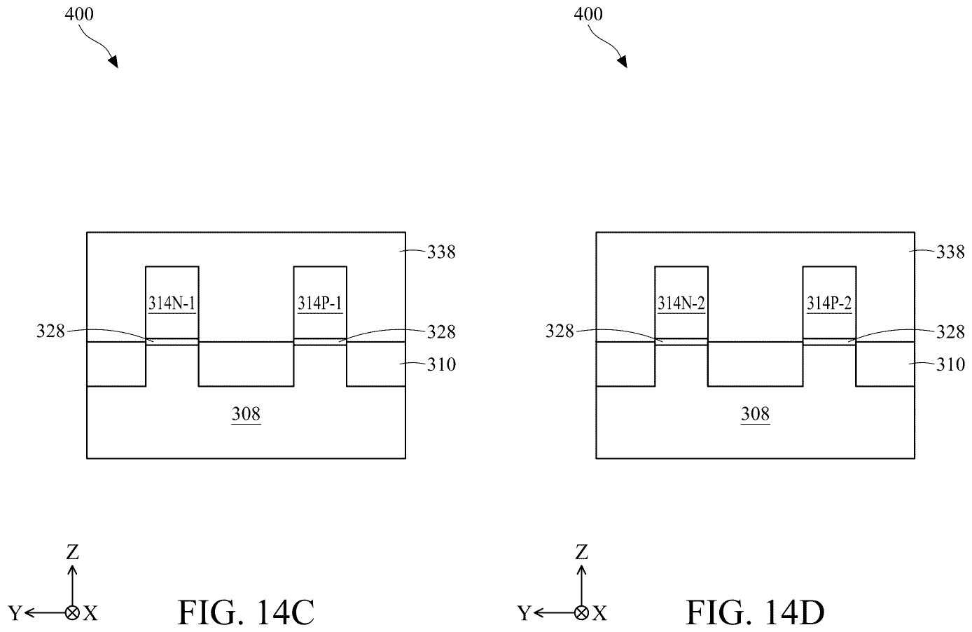

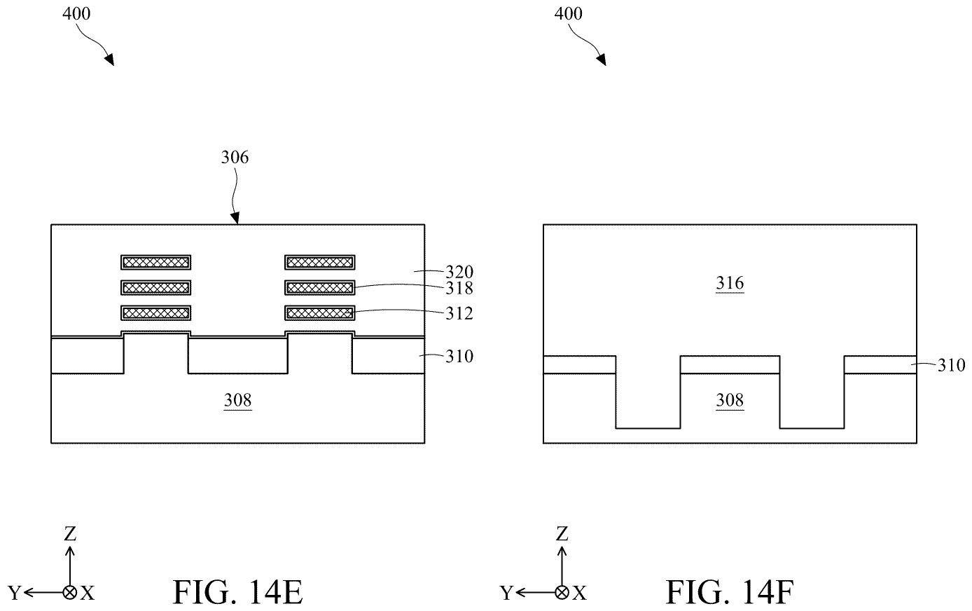

Referring to FIGS. 13 and 14A to 14F, after the formation of the ILD layer 338, the dielectric structures 316 discussed above are formed to replace the dummy gate structures 412-1 and 412-3, portions of the semiconductor layers 404 and 406 below the dummy gate structures 412-1 and 412-3, and portions of the substrate 308 and the isolation feature 310 below the dummy gate structures 412-1 and 412-3. In order to form the dielectric structures 316, one or more lithography and etching processes may be performed to remove the portions of the dummy gate structures 412 (the dummy gate structures 412-1 and 412-3) and the semiconductor layers 404 and 406 in regions to be formed the dielectric structures 316, and then the dielectric material for the dielectric structures 316 discussed above are formed in the regions to form the dielectric structures 316. As shown in FIG. 14F, portions of the substrate 308 and the isolation feature 310 in the regions to be formed the dielectric structures 316 are removed during the formation of the dielectric structures 316. Therefore, top surfaces of the substrate 308 and the isolation feature 310 under and attached to the dielectric structures 316 are lower than other top surfaces of the substrate 308 and the isolation feature 310.

Still referring to FIGS. 13 and 14A to 14F, after the formation of the dielectric structures 316, the gate structure 306 discussed above is formed to replace the dummy gate structure 412-2 and the semiconductor layers 404 below the dummy gate structure 412-2. More specifically, the dummy gate structure 412-2 is selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structure 412-2. Then, the dummy gate structure 412-2 is selectively etched through the masking element. Etch selectivity may be achieved by selecting the appropriate etching chemicals, and the dummy gate structure 412-2 may be removed without substantially affecting the gate spacers 322, the inner spacers 324, the substrate 308, and the isolation feature 310. The removal of the dummy gate structure 412-2 creates a gate trench exposing the top surfaces of the topmost semiconductor layers 406 underlies the dummy gate structure 412-2.

After the removal of the dummy gate structure 412-2, the semiconductor layers 404 in the fins 410 are selectively removed through the gate trench, using a wet or dry etching process for example, so that the semiconductor layers 406 in the fins 410 are exposed in the gate trench to form the channel layers 312 discussed above. Such a process may also be referred to as a wire release process, a nanowire release process, a nanosheet release process, a nanowire formation process, a nanosheet formation process, or a wire formation process. In some embodiments, the removal of the semiconductor layers 404 causes the exposed semiconductor layers 406 (the channel layers 312) to be spaced apart from each other in the vertical direction (e.g., in the Z-direction). The exposed semiconductor layers 406 (the channel layers 312) extend longitudinally in the horizontal direction (e.g., in the X-direction), and each connects one source/drain feature 314N/314P to another source/drain feature 314N/314P.

Still referring to FIGS. 13 and 14A to 14F, the gate structure 306 discussed above are formed in the gate trench to wrap around the semiconductor layers 406 (the channel layers 312). The gate structure 306 includes the gate dielectric layer 318 and the gate electrode layer 320 over the gate dielectric layer 318, as discussed above. In some embodiments, the gate dielectric layers 318 are formed to wrap around each of the semiconductor layers 406 (the channel layers 312). Additionally, the gate dielectric layer 318 is also formed on sidewalls of the inner spacers 324 and the gate spacers 322.

The gate electrode layer 320 is then formed to fill the remaining spaces of the gate trench, and over the gate dielectric layer 318 in such a way that the gate electrode layer 320 wraps around the semiconductor layers 406 (the channel layers 312), the gate dielectric layer 318, and the interfacial layers (if present). The gate electrode layer 320, the gate dielectric layer 318, and the interfacial layers (if present) may be collectively called as the gate structure 306 wrapping around the semiconductor layers 406 (the channel layers 312), as discussed above. After the formation of the gate structure 306, the N-type transistor NT and the P-type transistor PT is completely formed.

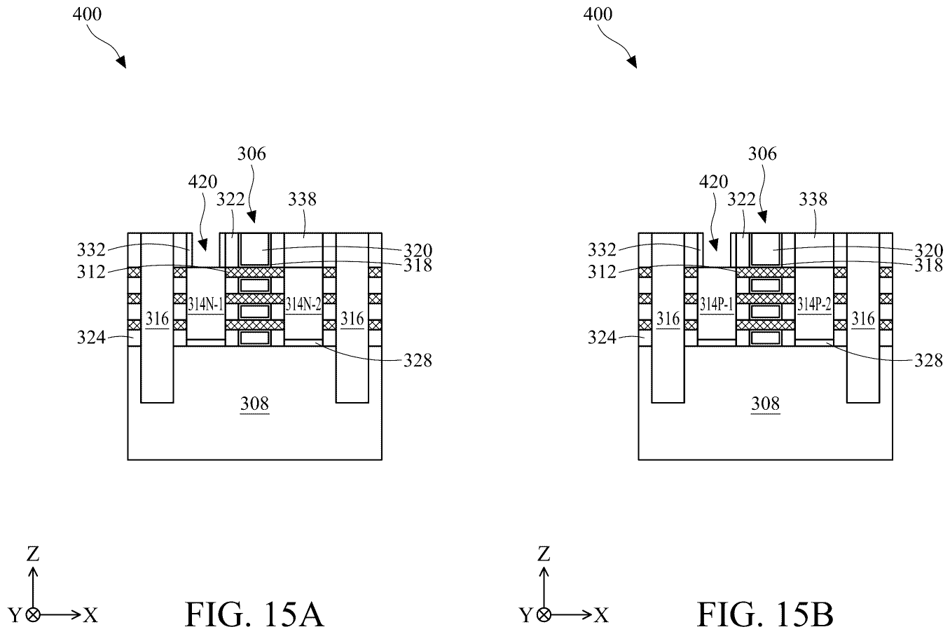

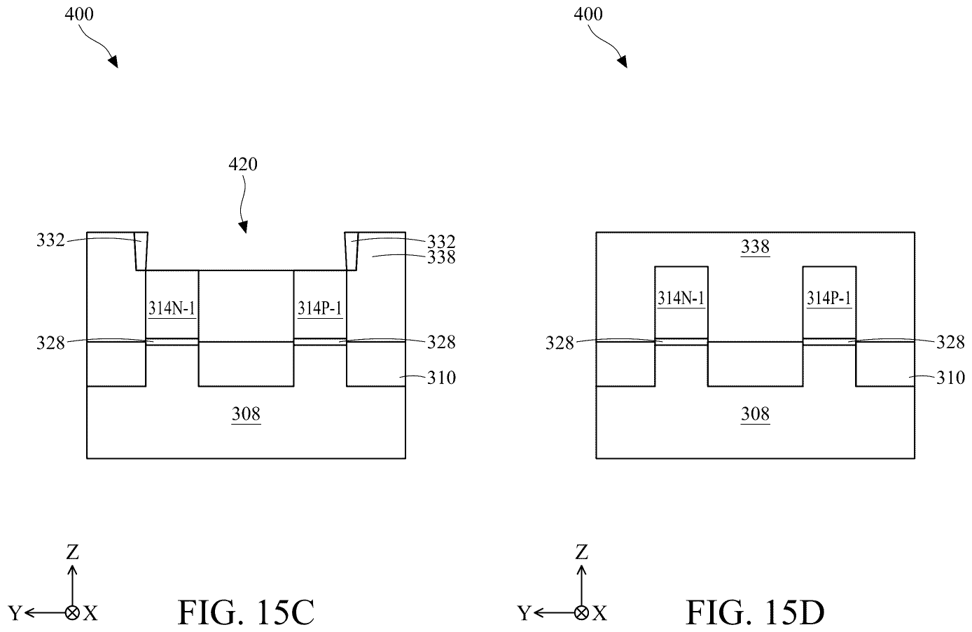

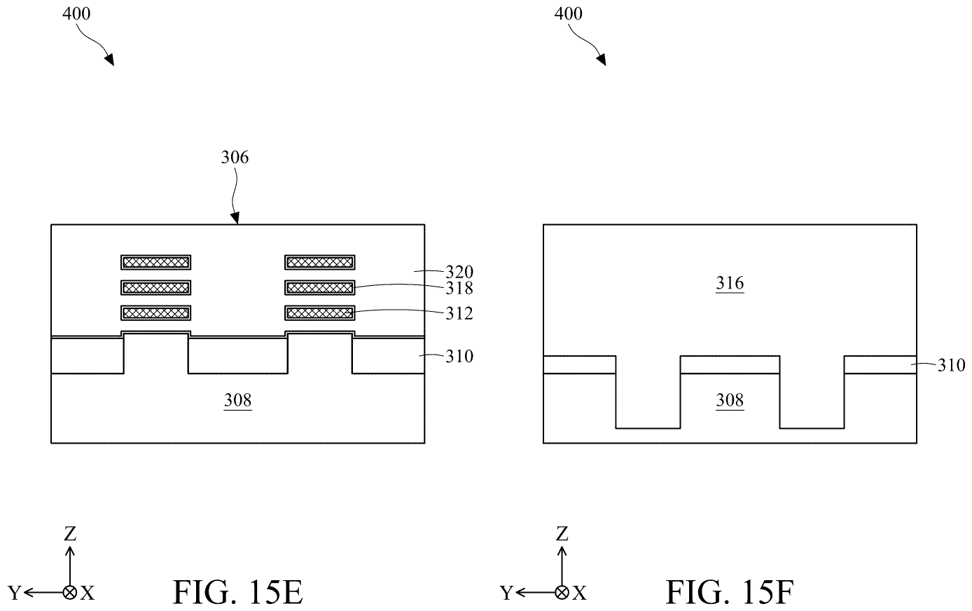

Referring to FIGS. 13 and 15A to 15F, after the formation of the gate structure 306, a portion of the ILD layer 338 is removed to form an opening 420. The opening 420 may be formed by performing one or more etching processes to remove a portion of the ILD layer 338 over the source/drain features 314N-1 and 314P-1. In some embodiments, the opening 420 exposes the top surfaces of the source/drain features 314N-1 and 314P-1.

Still referring to FIGS. 13 and 15A to 15F, after the formation of the opening 420, the interposing layer 332 discussed above is formed in the opening 420. More specifically, the interposing layer 332 is formed on sidewalls of the gate spacers 322 and the ILD layer 338 exposed in the opening 420. As shown in FIGS. 15A and 15B, the interposing layer 332 may also partially cover and be attached to the top surfaces of the source/drain features 314N-1 and 314P-1.

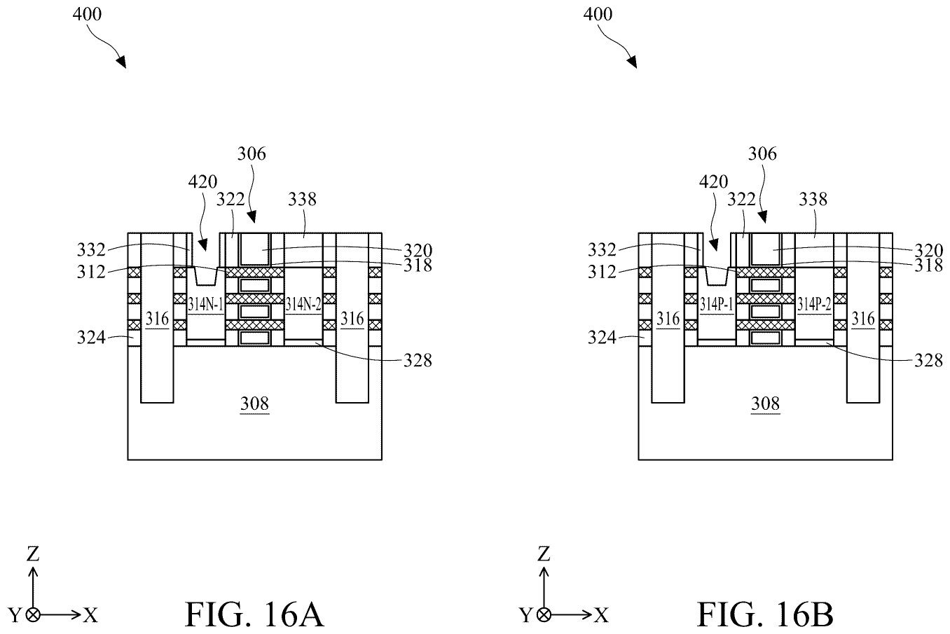

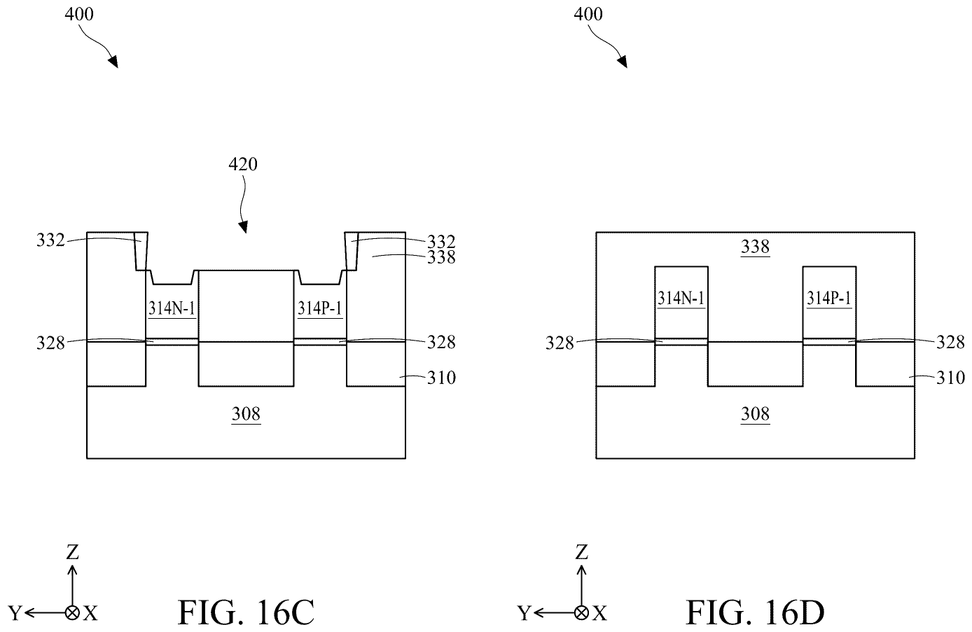

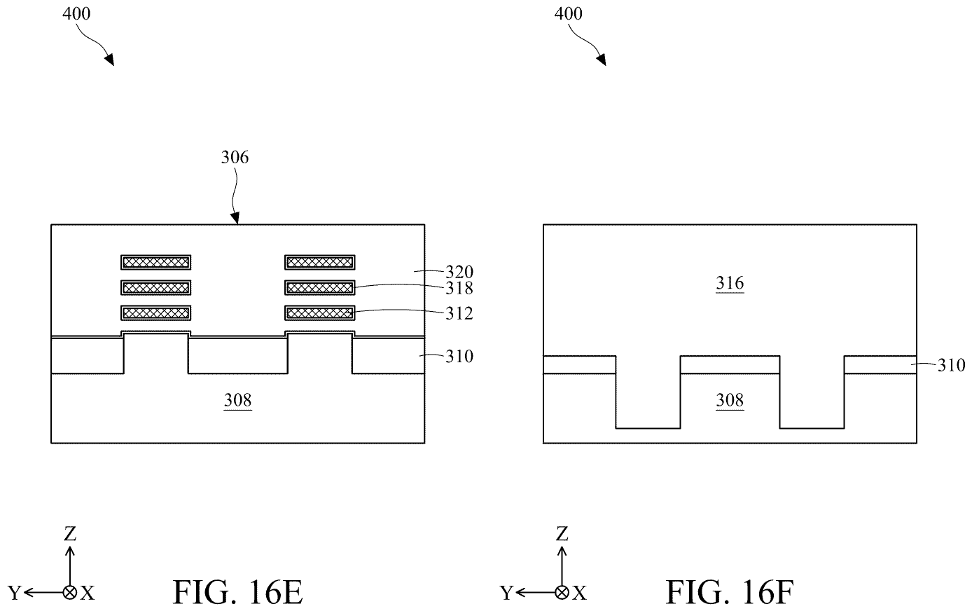

Referring to FIGS. 13 and 16A to 16F, after the formation of the interposing layer 332, portions of the source/drain features 314N-1 and 314P-1 are removed to enlarge the opening 420. More specifically, one or more etching processes is performed to partially remove the portions of the source/drain features 314N-1 and 314P-1, such that the source/drain features 314N-1 and 314P-1 is partially recessed, thereby enlarging the opening 420. In some embodiments, the enlarged portions of the enlarged opening 420 are used for the second portions 330t of the source/drain contact 330 discussed above.

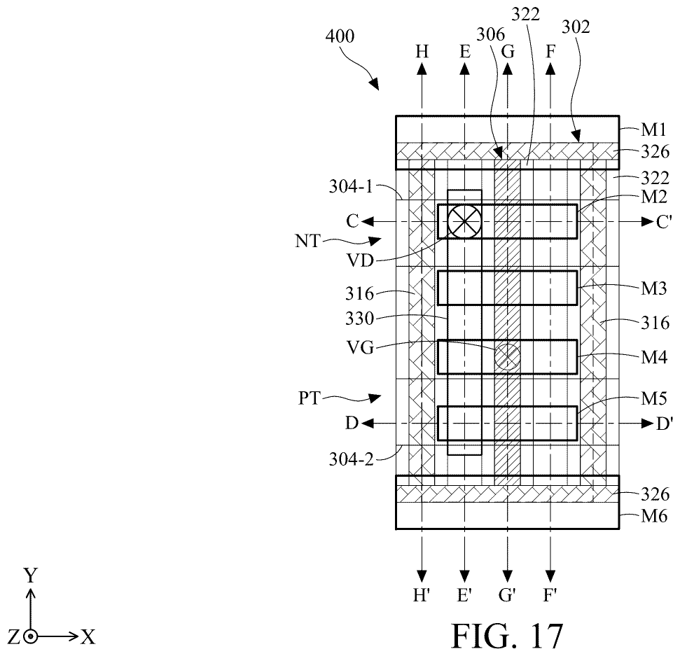

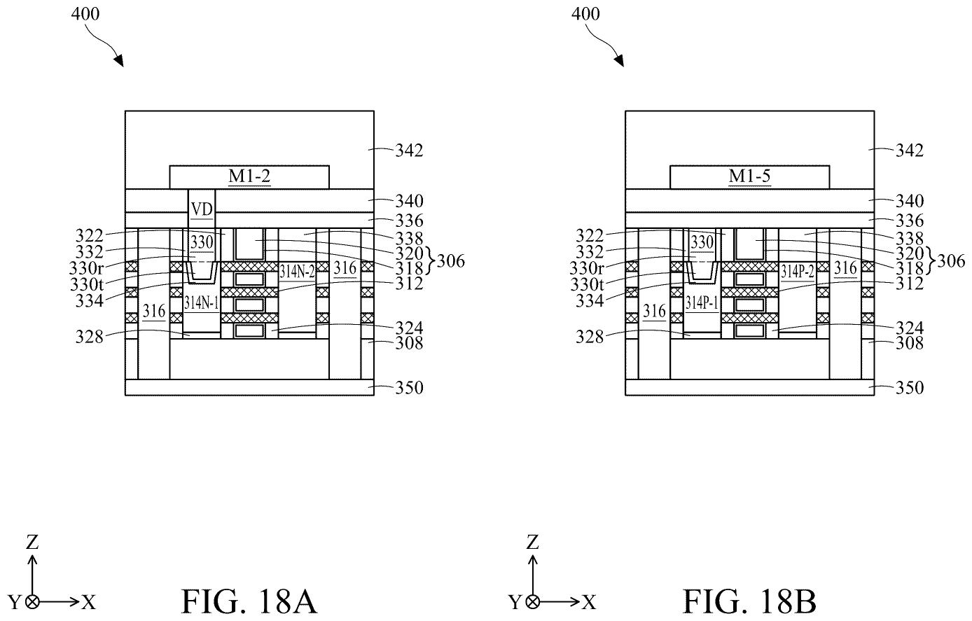

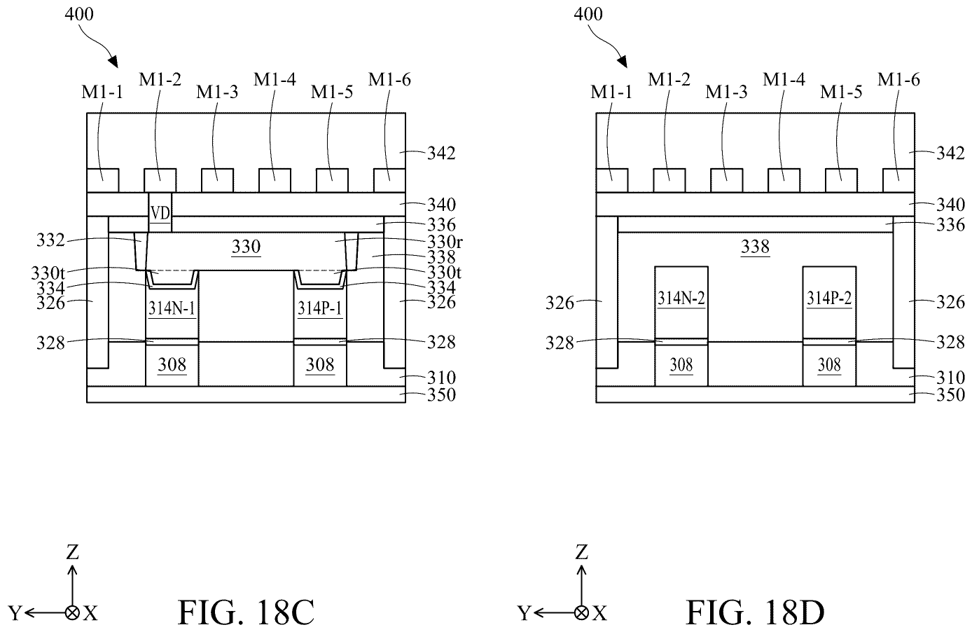

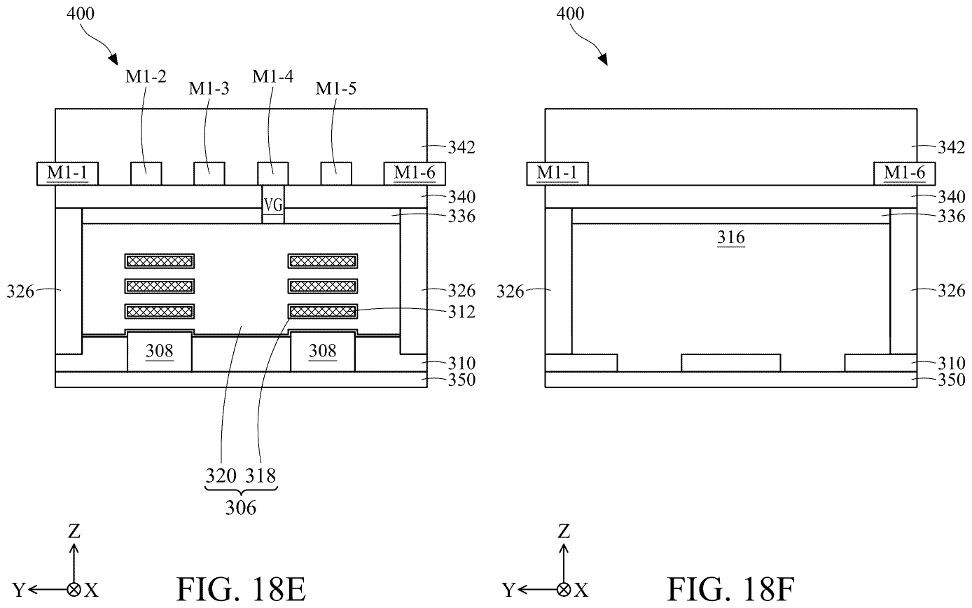

Referring to FIGS. 17 and 18A to 18F, after the removal of the portions of the source/drain features 314N-1 and 314P-1, the silicide layers 334 and the source/drain contact 330 discussed above are formed over the source/drain features 314N-1 and 314P-1 in the opening 420. Due to the shape of the enlarged opening 420 shown in FIGS. 16A to 16C, the silicide layers 334 are formed with the U-shape and the source/drain contact 330 is formed with the first portion 330r and the second portions 330t, as discussed above.

Still referring to FIGS. 17 and 18A to 18F, after the formation of the silicide layers 334 and the source/drain contact 330, the gate top dielectric layer 336 and the gate isolation features 326 discussed above are formed. The gate top dielectric layer 336 is formed over and cover the gate dielectric layer 318, the gate electrode layer 320, the dielectric structures 316, the source/drain contact 330, the interposing layer 332, the gate spacers 322, and the ILD layer 338. The gate isolation features 326 are then formed to cut the gate structure 306. As such, the gate isolation features 326 are formed on opposite sides of the gate structure 306 and the dielectric structures 316 in the Y-direction, as discussed above. The gate isolation features 326 also separate the gate structure 306 and/or the dielectric structures 316 from gate structures and/or dielectric structures of other transistor cells (not shown) in the semiconductor structure 300. In some embodiments, as shown in FIGS. 18C to 18F, the gate isolation features 326 pass through the ILD layer 338 and extend vertically into the isolation feature 310.

Still referring to FIGS. 17 and 18A to 18F, after the formation of the gate isolation features 326, the frontside interconnection structure including the ILD layer 340, the IMD layer 342, the gate via VG, the via VD, and the metal conductors M1-1 to M1-6 discussed above is formed over the gate top dielectric layer 336 and the gate isolation features 326. After the formation of the frontside interconnection structure, the workpiece 400 may be flipped to form the source/drain contacts 344 and the backside interconnection structure discussed above. For the purpose of simplicity, the sequent figures are shown without being flipped. Still referring to FIGS. 17 and 18A to 18F, a CMP process and/or other planarization process is performed on a bottom surface of the substrate 308 to remove a portion of the substrate 308. In other words, the substrate 308 is thinned (i.e., the thickness of the substrate 308 is reduced) by the CMP process and/or other planarization process. In some embodiments, portions of the dielectric structures 316 may be removed (specifically, be thinned) during the CMP process. Such CMP process and/or other planarization process is used for reducing the thickness of the substrate 308 to facilitate the formation of the source/drain contacts 344 and the backside interconnection structure.

Still referring to FIGS. 17 and 18A to 18F, after the CMP process, the IMD layer 350 discussed above is formed under the gate structure 306, the channel layers 312, the source/drain features 314N/314P, the bottom dielectric layers 328, the dielectric structures 316, the isolation feature 310, and the substrate 308. More specifically, the IMD layer 350 is formed under and attached to the dielectric structures 316, the isolation feature 310, and the substrate 308.

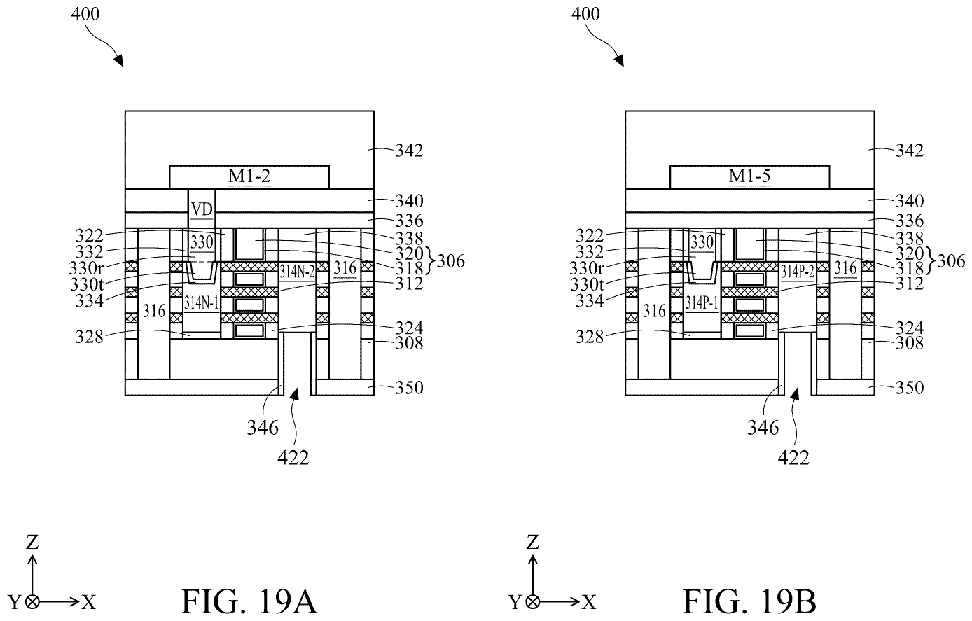

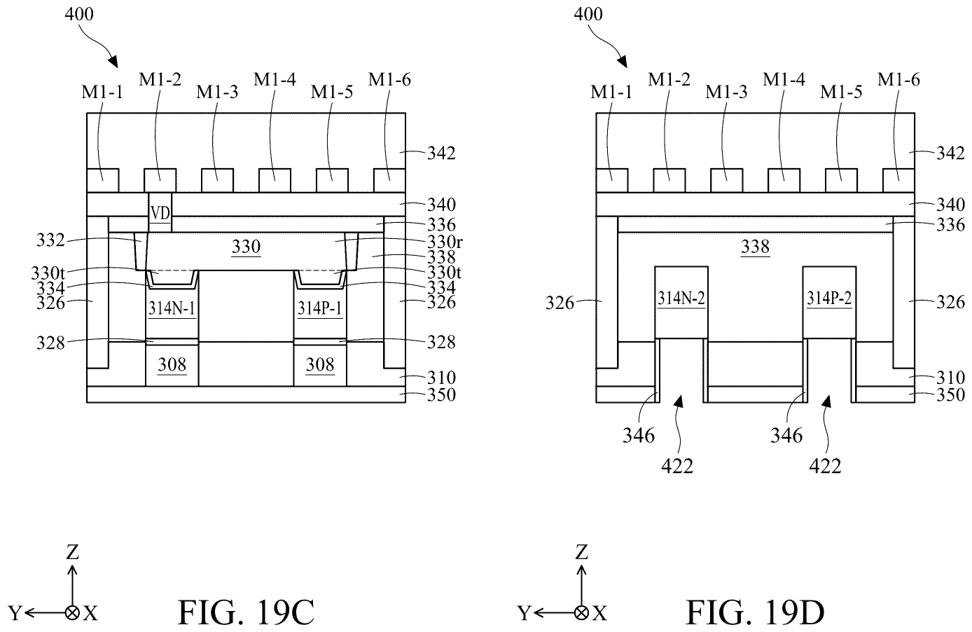

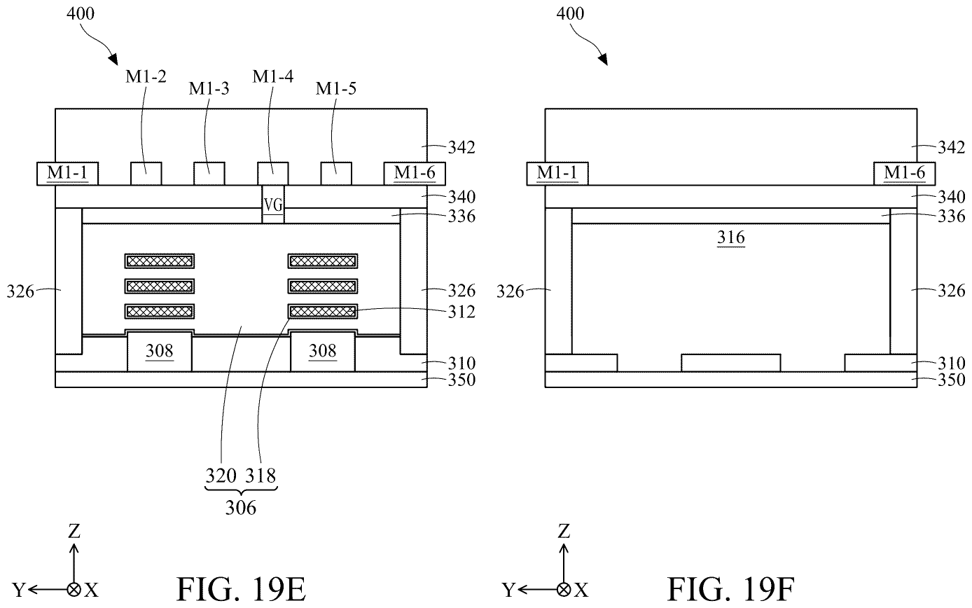

Referring to FIGS. 17 and 19A to 19F, after the formation of the IMD layer 350, portions of the IMD layer 350, the substrate 308, and the bottom dielectric layers 328 are removed to form openings 422. The openings 422 may be formed by performing one or more etching processes to remove the portions of the IMD layer 350, the substrate 308, and the bottom dielectric layers 328 below/under the source/drain features 314N-2 and 314P-2. In some embodiments, the openings 422 exposes the bottom surfaces of the source/drain features 314N-2 and 314P-2.

Still referring to FIGS. 17 and 19A to 19F, after the formation of the openings 422, the interposing layers 346 discussed above are formed in the openings 422. More specifically, the interposing layers 346 are formed on sidewalls of the substrate 308 and the IMD layer 350 exposed in the openings 422. Furthermore, due to the removal of the bottom dielectric layers 328 below/under the source/drain features 314N-2 and 314P-2, the interposing layers 346 are also partially formed on sidewalls of the inner spacers 324 and the ILD layer 338 exposed in the openings 422, as shown in FIGS. 19A, 19B, and 19D. As shown in FIGS. 19A and 19B, the interposing layers 346 may also partially cover and be attached to the bottom surfaces of the source/drain features 314N-2 and 314P-2.

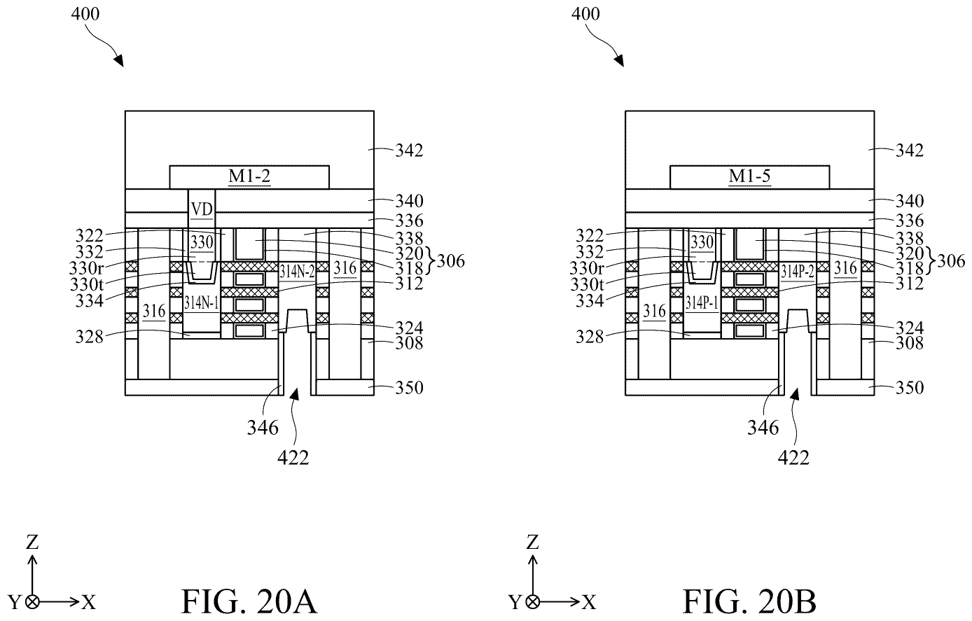

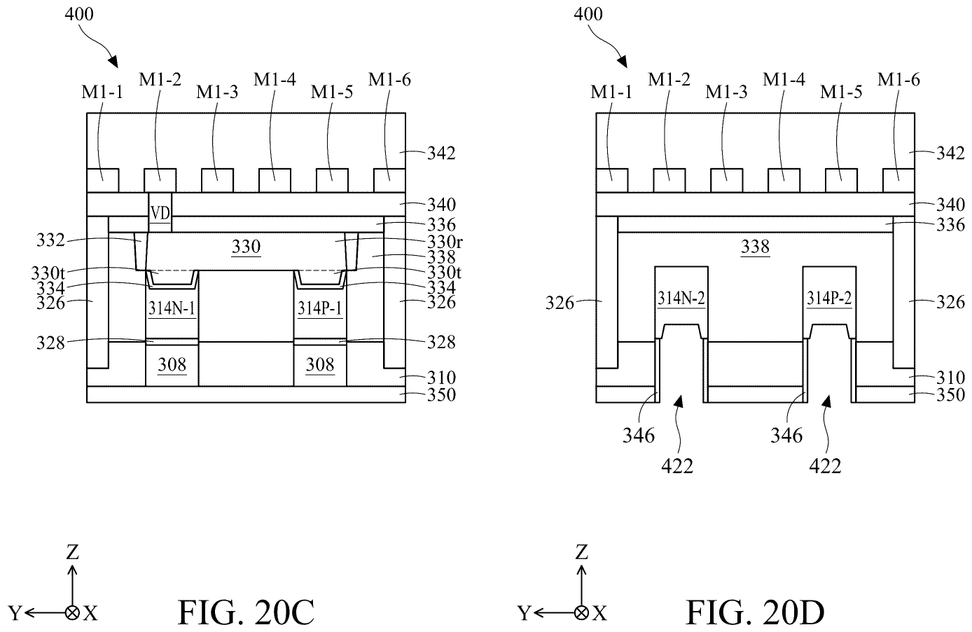

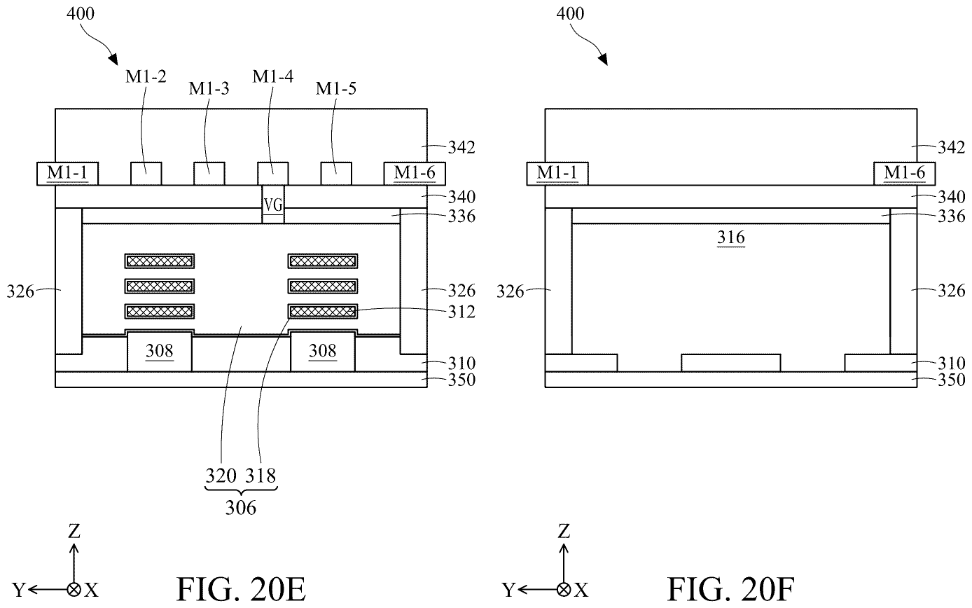

Referring to FIGS. 17 and 20A to 20F, after the formation of the interposing layers 346, portions of the source/drain features 314N-2 and 314P-2 are removed to enlarge the openings 422. More specifically, one or more etching processes is performed to partially remove the portions of the source/drain features 314N-2 and 314P-2, such that the source/drain features 314N-2 and 314P-2 is partially recessed, thereby enlarging the openings 422. In some embodiments, the enlarged portions of the enlarged openings 422 are used for the second portions 344t of the source/drain contacts 344 discussed above.

Referring back to FIGS. 6A to 6H, after the removal of the portions of the source/drain features 314N-2 and 314P-2, the silicide layers 348 and the source/drain contacts 344 discussed above are formed under the source/drain features 314N-2 and 314P-2 in the openings 422. Due to the shape of the enlarged openings 422 shown in FIGS. 20A to 20D, the silicide layers 348 are formed with the (inverted) U-shape and the source/drain contacts 344 are formed with the first portions 344r and the second portions 344t, as discussed above.

After the formation of the silicide layers 348 and the source/drain contacts 344, the backside interconnection structure including the IMD layer 352 and the metal conductors BM1-1 and BM1-2 discussed above is formed under the source/drain contacts 344 and the IMD layer 350. As such, the workpiece 400 is completely formed to have transistors with the backside interconnection structure and the source/drain contacts deep into the source/drain features for presenting the exemplary fabrication of the transistors in the transistor cell 302 discussed above.

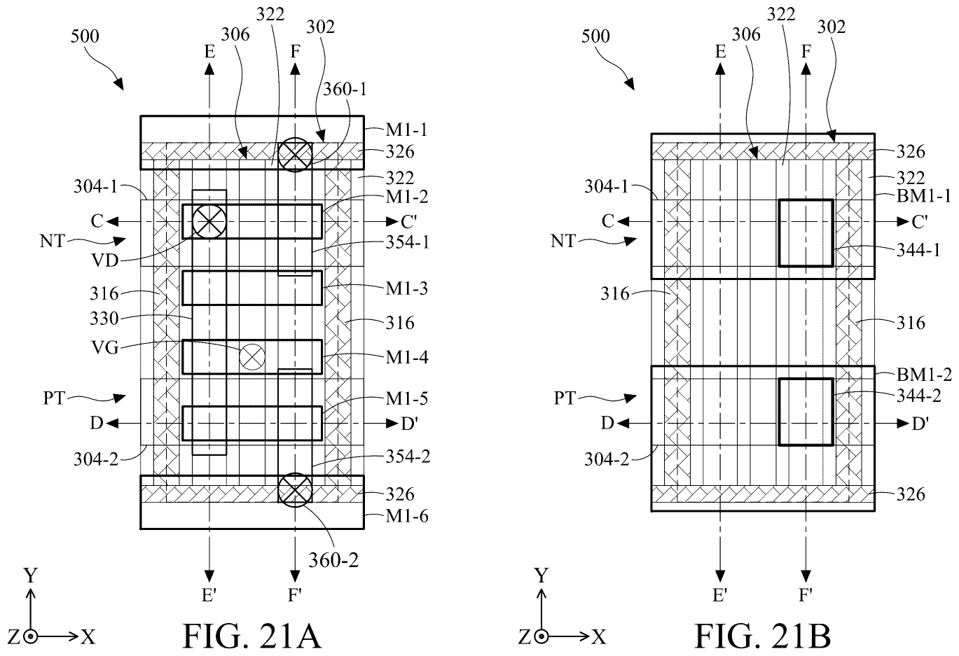

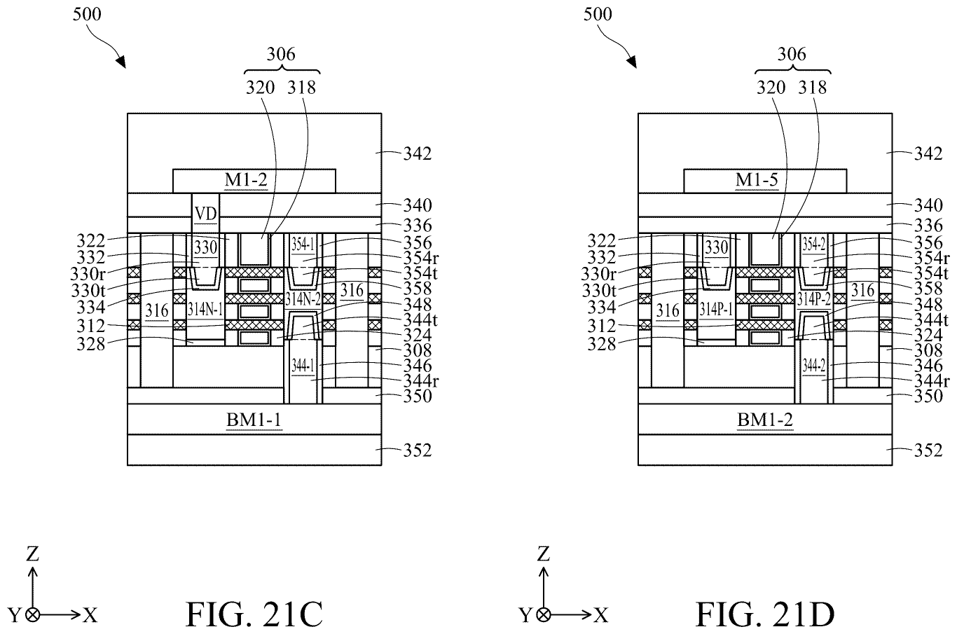

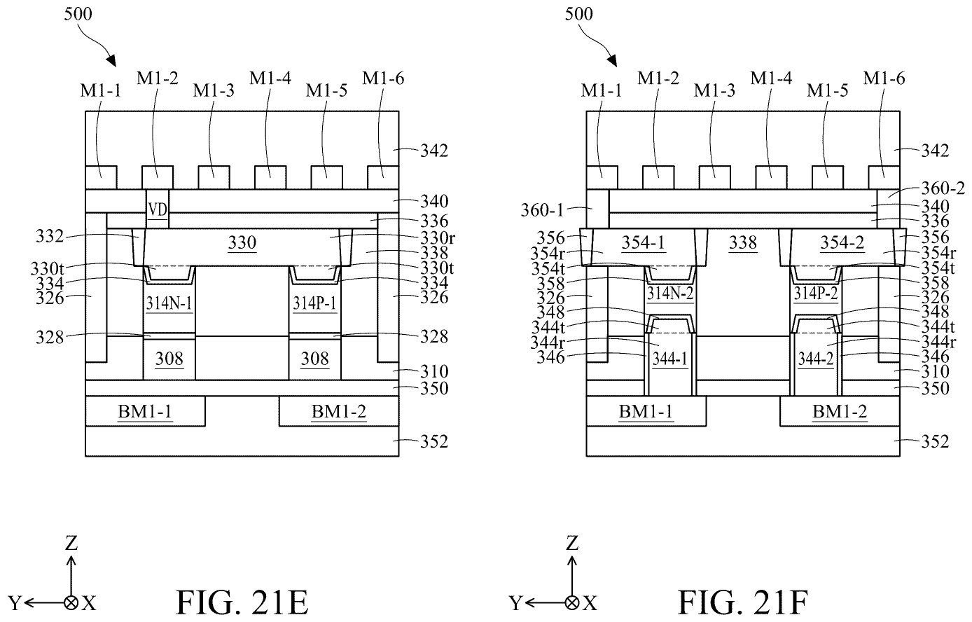

FIGS. 21A and 21B are top views (or layouts) of a semiconductor structure 500 that can be one embodiment of transistor cells implemented in the memory region 20 or the logic region 30 of the IC chip 10, in which FIG. 21A illustrates the features in the device region and the frontside interconnection structure, and FIG. 21B illustrates the features in the device region and the backside interconnection structure. FIGS. 21C and 21D are X-Z cross-sectional views of the semiconductor structure 500 along lines C-C′ and D-D′ of FIGS. 21A and 21B, respectively, in accordance with some alternative embodiments of the present disclosure. FIGS. 21E and 21F are Y-Z cross-sectional view of the semiconductor structure 500 along lines E-E′ and F-F′ of FIGS. 21A and 21B, respectively, in accordance with some alternative embodiments of the present disclosure.

The semiconductor structure 500 is similar to the semiconductor structure 300 discussed above, except that the semiconductor structure 500 further includes source/drain contacts 354-1 and 354-2 (may be collectively referred to as the source/drain contacts 354), interposing layers 356, silicide layers 358, and vias 360-1 and 360-2. As shown in FIGS. 21A to 21F, the source/drain contacts 354-1 and 354-2 are respectively over and electrically connected to the source/drain feature 314N-2 of the N-type transistor NT and the source/drain feature 314P-2 of the P-type transistor PT. The source/drain contacts 354 extend lengthwise the Y-direction, as shown in FIGS. 21A and 21F. In some embodiments, top surfaces of the source/drain contacts 354 are substantially level with the top surface of the gate structure 306, as shown in FIGS. 21C and 21D. The source/drain contacts 354 are over the source/drain features 314N-2 and 314P-2, such that the source/drain contacts 354 may be referred to as the frontside source/drain contact.

As shown in FIGS. 21C to 21F, in the X-Z and Y-Z cross-sectional views, similar to the source/drain contact 330, portions of the source/drain contacts 354 each extend into the source/drain features 314N-2 or 314P-2. More specifically, each of the source/drain contacts 354 has a first portion 354r extending away from the source/drain feature 314N-2 or 314P-2 and a second portion 354t extending into the source/drain feature 314N-2 or 314P-2, as shown in FIGS. 21C to 21F. Therefore, each of the second portions 354t of the source/drain contacts 354 is surrounded by the source/drain feature 314N-2 or 314P-2. The second portions 354t are under the first portions 354r. Furthermore, bottom surfaces of the source/drain contacts 354 are lower than the bottom surfaces of topmost channel layers 312, as shown in FIGS. 21C and 21D. In other words, bottom surfaces of the second portions 354t of the source/drain contacts 354 are lower than the bottom surfaces of topmost channel layers 312. The source/drain contacts 354 may include a conductive material as that of the source/drain contacts 330 and 344 discussed above. In some embodiments, the first portion 354r is wider than the second portion 354t. In some embodiments, the second portion 354t has slope sidewalls extending in the source/drain feature 314N-2 or 314P-2. In some embodiments, the width of the second portion 354t gradually decreases from its top portion to its bottom portion. In some embodiments, the top width of the second portion 354t is greater than the bottom width of the second portion 354t. It is noted that although the first portion 354r and the second portion 354t are described as two portions, there are no real interface therebetween.

Still referring to FIGS. 21C to 21F, the interposing layers 356 are on sidewalls of the source/drain contacts 354 and over the source/drain features 314N-2 and 314P-2. More specifically, the interposing layers 356 is on sidewalls of the first portions 354r of the source/drain contacts 354. In some aspects, the interposing layers 356 surround the sidewalls of the first portions 354r of the source/drain contacts 354, as shown in FIGS. 21C to 21F. In some embodiment, the interposing layers 356 is the nitrogen content dielectric layer. In some embodiment, the interposing layers 356 is the nitrogen containing oxide layer, such as SiON or SiOCN. Therefore, the interposing layers 356 have lower dielectric constant (k value) than nitride layer (e.g., silicon nitride) for protecting the substrate 308 in the formation of the silicide layers 358 with low parasitic capacitance. As shown in FIGS. 21C to 21F, the interposing layers 356 are between and attached to the source/drain contacts 354 and the gate spacers 322 in the X-direction to improve the isolation margin for the source/drain contacts 354 to the gate structure 306.

Still referring to FIGS. 21C to 21F, the silicide layers 358 are over and attached to the source/drain features 314N-2 and 314P-2, and under the and attached to the source/drain contacts 354. More specifically, the silicide layers 358 are between the source/drain contacts 354 and the source/drain feature 314N-2/314P-2. The silicide layers 358 are on sidewalls of the second portions 354t of the source/drain contacts 354. In some aspects, the silicide layers 358 surround the sidewalls of the second portions 354t of the source/drain contacts 354, as shown in FIGS. 21C to 21F. In some embodiments, bottom surfaces of the silicide layers 358 are lower than the bottom surfaces of the topmost channel layers 312, as shown in FIGS. 21C and 21D. The silicide layers 358 may include a material as that of the silicide layers 334 and 348 discussed above.

Still referring to FIGS. 21C to 21F, the frontside interconnection structure further includes the vias 360-1 and 360-2 disposed in the ILD layer 340. The vias 360-1 and 360-2 are respectively over and attached to the source/drain contacts 354-1 and 354-2 and electrically connects the source/drain contacts 354-1 and 354-2 to the metal conductors M1-1 and M1-6, respectively. In the present embodiments, the metal conductors M1-1 and M1-6 respectively serve as VSS line and VDD line as the metal conductors BM1-1 and BM1-2 discussed above. More specifically, the metal conductor M1-1 is over and electrically connected to the source/drain feature 314N-2 of the N-type transistor NT through the via 360-1, the source/drain contact 354-1, and the silicide layer 358, and the metal conductor M1-6 is over and electrically connected to the source/drain feature 314P-2 of the P-type transistor PT through the via 360-2, the source/drain contact 354-2, and the silicide layer 358, as shown in FIGS. 21A to 21F. Therefore, VSS voltage (or ground voltage) and the VDD voltage are respectively supplied to the source/drain feature 314N-2 of the N-type transistor NT and the source/drain feature 314P-2 of the P-type transistor PT.

Therefore, each of the source/drain features 314N-2 and 314P-2 is electrically connected to and powered from one frontside metal conductor and one backside metal conductor. Such embodiments can be seen that the metal conductors M1-1 and BM1-1 electrically connected with each other in parallel and the metal conductors M1-6 and BM1-2 electrically connected with each other in parallel, such that the total resistance of the metal conductors are reduced, thereby improving the performance of the semiconductor structure 500.

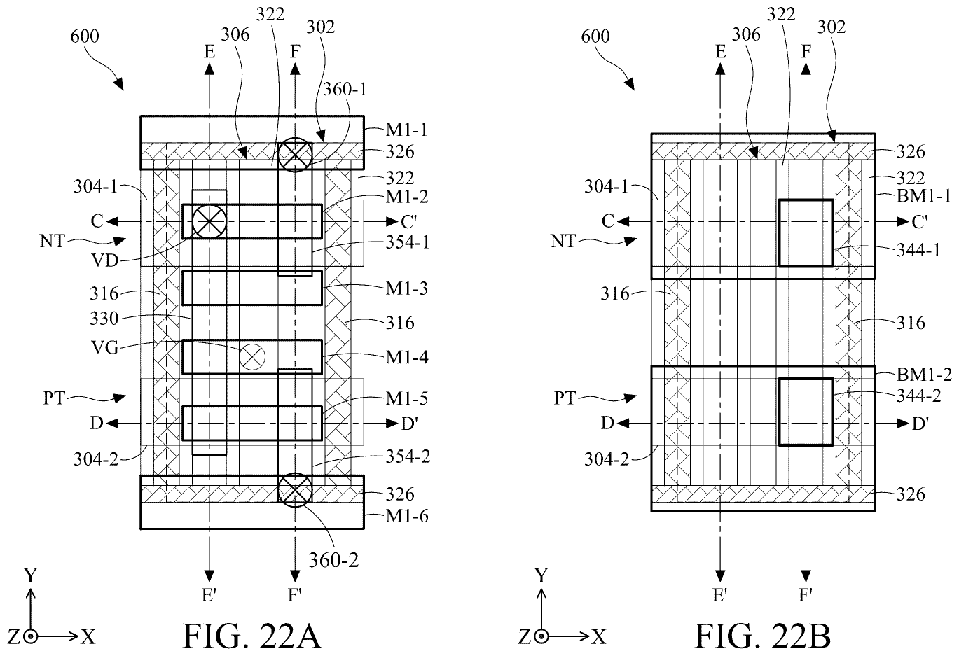

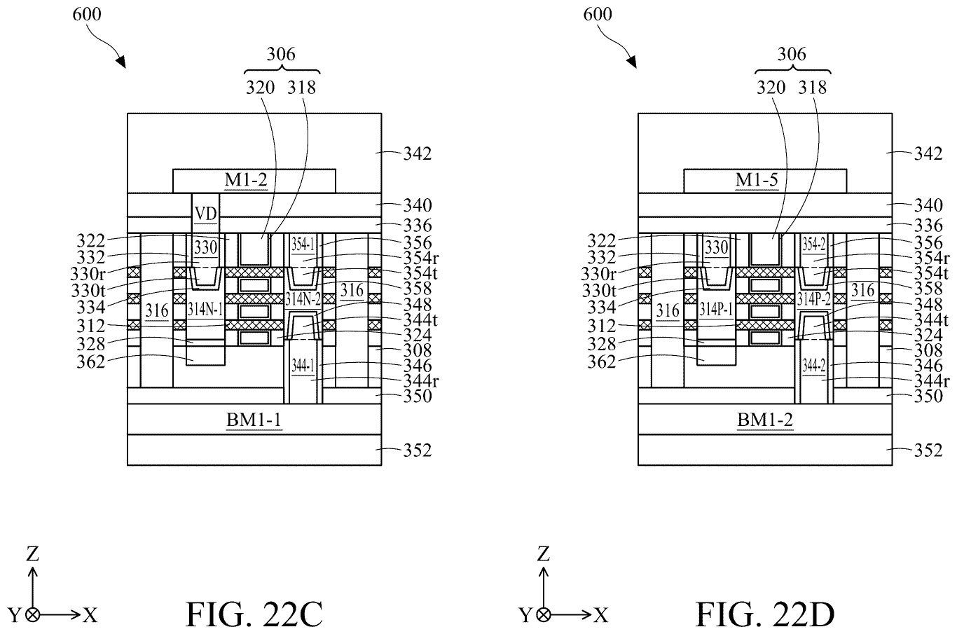

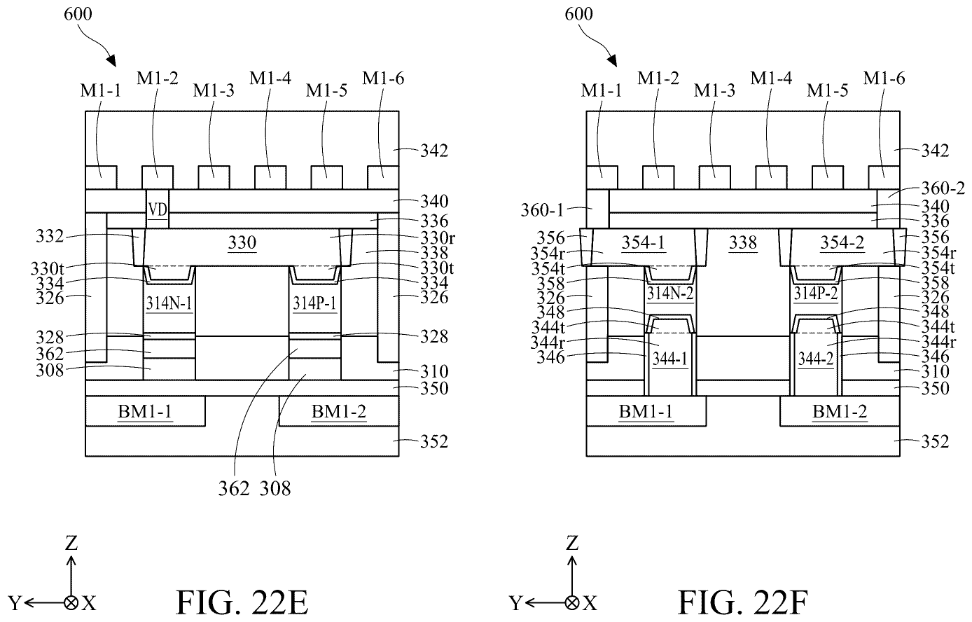

FIGS. 22A and 22B are top views (or layouts) of a semiconductor structure 600 that can be one embodiment of transistor cells implemented in the memory region 20 or the logic region 30 of the IC chip 10, in which FIG. 22A illustrates the features in the device region and the frontside interconnection structure, and FIG. 22B illustrates the features in the device region and the backside interconnection structure. FIGS. 22C and 22D are X-Z cross-sectional views of the semiconductor structure 600 along lines C-C′ and D-D′ of FIGS. 22A and 22B, respectively, in accordance with some alternative embodiments of the present disclosure. FIGS. 22E and 22F are Y-Z cross-sectional view of the semiconductor structure 600 along lines E-E′ and F-F′ of FIGS. 22A and 22B, respectively, in accordance with some alternative embodiments of the present disclosure.

The semiconductor structure 600 is similar to the semiconductor structure 500 discussed above, except that the semiconductor structure 600 further includes SiGe layers 362 under and attached to the bottom dielectric layers 328 below the source/drain features 314N-1 and 314P-1, and over and attached to the substrate 308. In some aspects, the SiGe layers 362 is between the bottom dielectric layers 328 and the substrate 308. In some embodiments, a thickness of the SiGe layers 362 is in a range from about 15 nm to about 80 nm. The SiGe layers 362 are formed before the formation of the bottom dielectric layers 328 shown in FIGS. 12A to 12F. In fact, the SiGe layers 362 are formed are also formed under the bottom dielectric layers 328 below the source/drain features 314N-2 and 314P-2, but the SiGe layers 362 below the source/drain features 314N-2 and 314P-2 are removed during the formation of the source/drain contacts 344. The SiGe layers 362 may facilitate the formation of the source/drain contacts 344. More specifically, the source/drain contacts 344 can be formed using self-aligned process, such that the process window of the formation of the source/drain contacts 344 is increased.

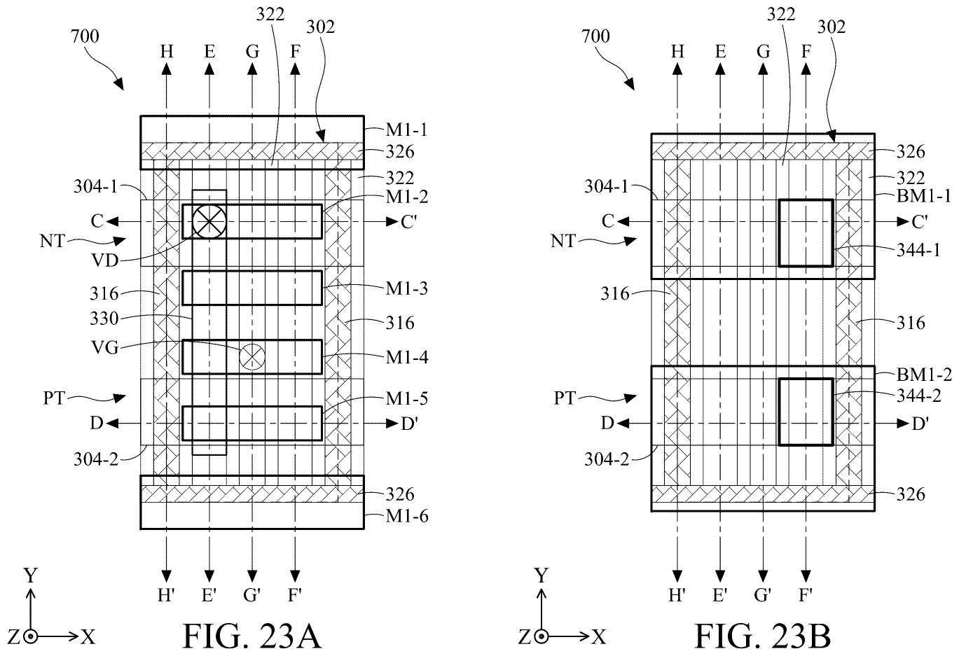

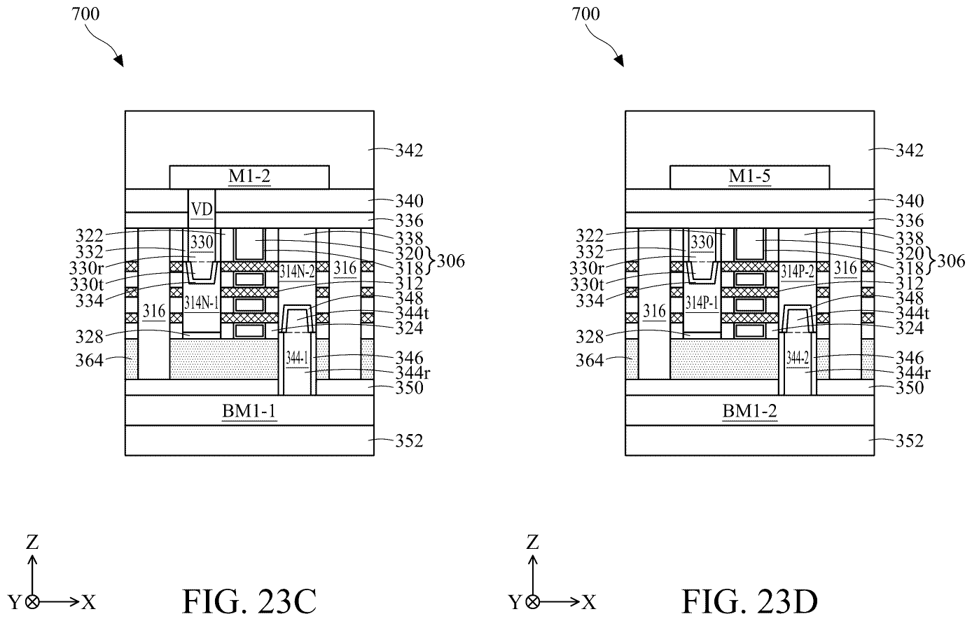

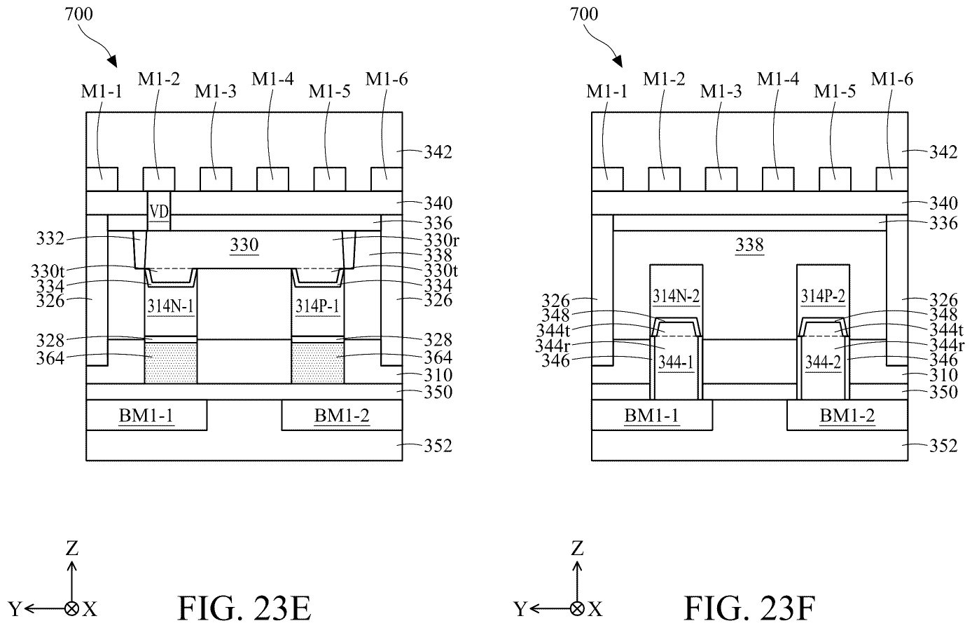

FIGS. 23A and 23B are top views (or layouts) of a semiconductor structure 700 that can be one embodiment of transistor cells implemented in the memory region 20 or the logic region 30 of the IC chip 10, in which FIG. 23A illustrates the features in the device region and the frontside interconnection structure, and FIG. 23B illustrates the features in the device region and the backside interconnection structure. FIGS. 23C and 23D are X-Z cross-sectional views of the semiconductor structure 700 along lines C-C′ and D-D′ of FIGS. 23A and 23B, respectively, in accordance with some alternative embodiments of the present disclosure. FIGS. 23E and 23F are Y-Z cross-sectional view of the semiconductor structure 700 along lines E-E′ and F-F′ of FIGS. 23A and 23B, respectively, in accordance with some alternative embodiments of the present disclosure.

The semiconductor structure 700 is similar to the semiconductor structure 300 discussed above, except that the semiconductor structure 700 further includes a dielectric layer 364 replacing the substrate 308. More specifically, after the CMP process and/or other planarization process performed on the substrate 308 discussed in FIGS. 17 and 18A to 18F, the substrate 308 is removed by a selective etching process, and the dielectric layer 364 is then formed under and attached to (the bottom surfaces of) the gate structure 306, the inner spacers 324, the bottom dielectric layers 328, and the dielectric structures 316. After the formation of the dielectric layer 364, the IMD layer 350, the dielectric layers 346, the silicide layers 348, the source/drain contacts 344, the IMD layer 352, the metal conductor BM1-1, and the metal conductor BM1-2 discussed above are sequentially formed. Furthermore, the dielectric layer 364 is also on and attached to the sidewalls of the dielectric structures 316, the isolation feature 310, and the interposing layers 346. In some embodiments, the source/drain contacts 344 pass through dielectric layer. Due to the dielectric layer 364 replacing the substrate 308, the parasitic capacitance of the gate structure 306 is reduced.

In some embodiments, the dielectric material of the dielectric layer 364 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof.

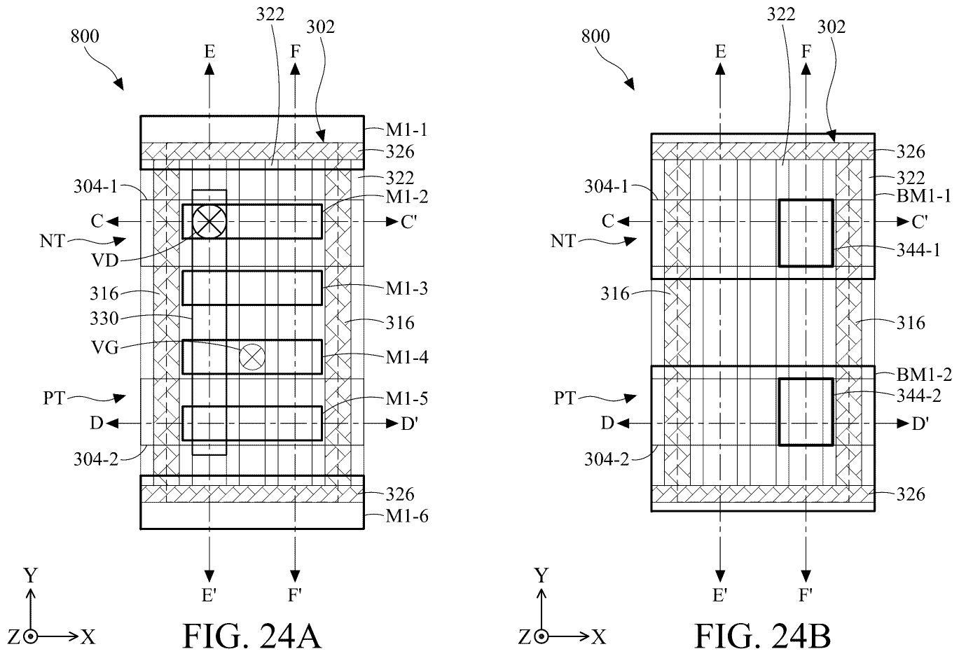

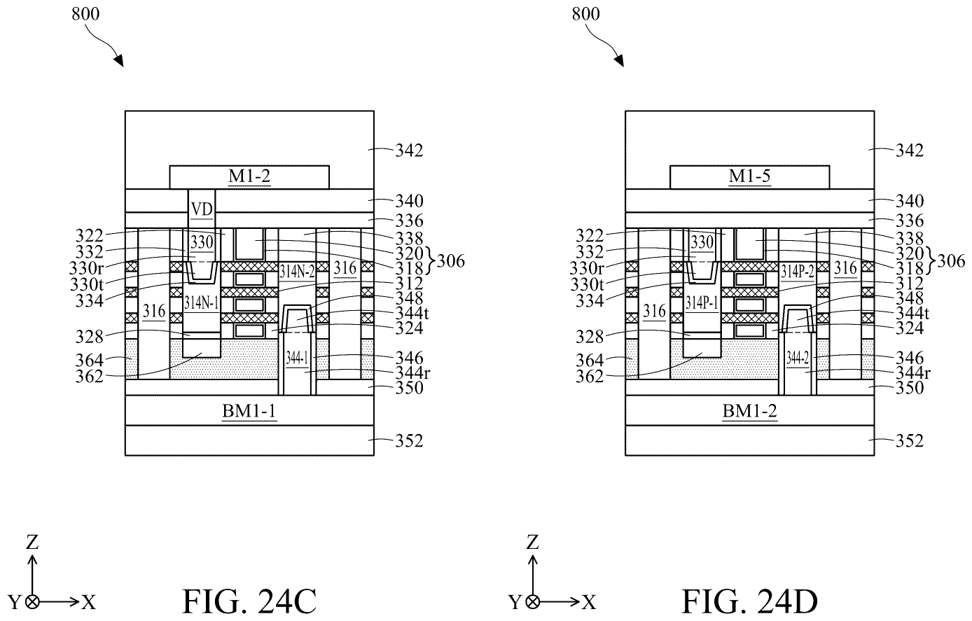

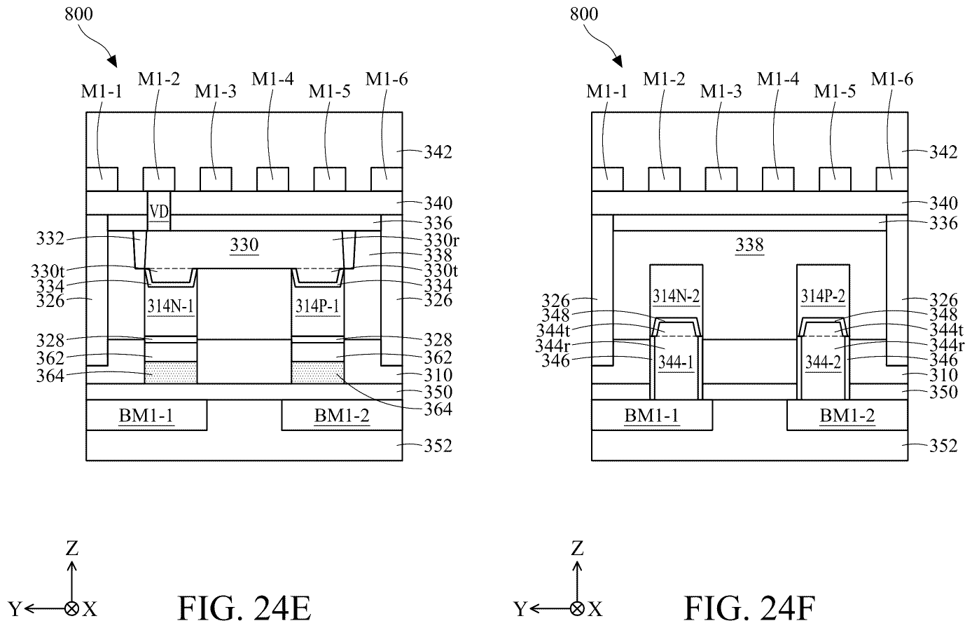

FIGS. 24A and 24B are top views (or layouts) of a semiconductor structure 800 that can be one embodiment of transistor cells implemented in the memory region 20 or the logic region 30 of the IC chip 10, in which FIG. 24A illustrates the features in the device region and the frontside interconnection structure, and FIG. 24B illustrates the features in the device region and the backside interconnection structure. FIGS. 24C and 24D are X-Z cross-sectional views of the semiconductor structure 800 along lines C-C′ and D-D′ of FIGS. 24A and 24B, respectively, in accordance with some alternative embodiments of the present disclosure. FIGS. 24E and 24F are Y-Z cross-sectional view of the semiconductor structure 800 along lines E-E′ and F-F′ of FIGS. 24A and 24B, respectively, in accordance with some alternative embodiments of the present disclosure.

The semiconductor structure 800 is similar to the semiconductor structure 700 discussed above, except that the semiconductor structure 800 further includes the SiGe layers 362 under and attached to the bottom dielectric layers 328 below the source/drain features 314N-1 and 314P-1, and over and attached to the dielectric layer 364. In some aspects, the SiGe layers 362 is between the bottom dielectric layers 328 and the dielectric layer 364. The function and effect of the SiGe layers 362 as that discussed above.

The embodiments disclosed herein relate to semiconductor devices, and more particularly to semiconductor structures including source/drain contacts deep into source/drain features, such that the current crowding and source/drain resistance are reduced. Furthermore, the present embodiments provide one or more of the following advantages. The metal conductors for VDD lines and VSS lines are disposed in the backside interconnection structure under the transistor cell to relieve the space at the frontside interconnection structure. The routing complexity at the frontside interconnection structure is reduced.

Thus, one of the embodiments of the present disclosure describes a semiconductor structure that includes a transistor. The transistor cell includes channel layers vertically stacked from each other, a gate structure interfacing at least three surfaces of each of the channel layers, and a first source/drain feature and a second source/drain feature on opposite sides of the gate structure. The semiconductor structure further includes a first source/drain contact over and electrically connected to the first source/drain feature, a second source/drain contact under and electrically connected to the second source/drain feature, and an inter-layer dielectric layer surrounding the first source/drain contact and the second source/drain contact. A bottom surface of the first source/drain contact is lower than a bottom surface of a topmost channel layer of the channel layers. A top surface of the second source/drain contact is higher than a top surface of a bottommost channel layer of the channel layers. Conductivity of the first source/drain contact and the second source/drain contact is greater than that of the first source/drain feature and the second source/drain feature.

In another of the embodiments, discussed is a semiconductor structure including a first active area and a second active area extending in a first direction, an isolation feature between the first active area and the second active area in a second direction perpendicular to the first direction, a gate structure across the first active area and the second active area and interfacing a top surface of the isolation feature, source/drain features on opposite sides of the gate structure, a first source/drain contact electrically connected to a first one of the source/drain features, and a second source/drain contact electrically connected to a second one of the source/drain features. The first source/drain contact includes a first portion and a second portion under the first portion and surrounded by the first one of the source/drain features. The second source/drain contact includes a third portion and a fourth portion over the third portion and surrounded by the second one of the source/drain features.

In yet another of the embodiments, discussed is a semiconductor structure that includes channel layers over a substrate, a gate structure interfacing at least three surfaces of each of the channel layers, gate spacers on opposite sides of the gate structure in a first direction, a first source/drain feature and a second source/drain feature attached to the channel layers, gate isolation features attached to the gate structure and gate spacers in a second direction perpendicular to the first direction, a frontside source/drain contact over and electrically connected to the first source/drain feature, a first silicide layer between the frontside source/drain contact and the first source/drain feature, a backside source/drain contact under and electrically connected to the second source/drain feature, and a second silicide layer between the backside source/drain contact and the second source/drain feature. Bottom surfaces of the gate isolation features are lower than a bottom surface of the gate structure. A bottom surface of the first silicide layer is lower than a topmost channel layer of the channel layers. A top surface of the second silicide layer is higher than a bottommost channel layer of the channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a transistor, comprising:
channel layers vertically stacked from each other;
a gate structure interfacing at least three surfaces of each of the channel layers; and
a first source/drain feature and a second source/drain feature on opposite sides of the gate structure;
a first source/drain contact over and electrically connected to the first source/drain feature, wherein a bottom surface of the first source/drain contact is lower than a bottom surface of a topmost channel layer of the channel layers; and
a second source/drain contact under and electrically connected to the second source/drain feature, wherein a top surface of the second source/drain contact is higher than a top surface of a bottommost channel layer of the channel layers, wherein conductivity of the first source/drain contact and the second source/drain contact is greater than that of the first source/drain feature and the second source/drain feature;
an inter-layer dielectric layer surrounding the first source/drain contact and the second source/drain contact.

2. The semiconductor structure of claim 1, wherein each of the first source/drain contact and the second source/drain contact comprises a first portion extending over the first source/drain feature or the second source/drain feature and a second portion extending into the first source/drain feature or the second source/drain feature.

3. The semiconductor structure of claim 2, further comprising:
interposing layers on sidewalls of the first portions of the first source/drain contact and the second source/drain contact.

4. The semiconductor structure of claim 3, wherein a top surface of the dielectric layer on the sidewalls of the first portions of the second source/drain contact is higher than a bottom surface of the gate structure.

5. The semiconductor structure of claim 2, further comprising:
silicide layers surrounding sidewalls of the second portions of the first source/drain contact and the second source/drain contact.

6. The semiconductor structure of claim 1, further comprising:
a third source/drain contact over and electrically connected to the second source/drain feature, wherein a bottom surface of the third source/drain contact is lower than the bottom surface of the topmost channel layer of the channel layers.

7. The semiconductor structure of claim 6, further comprising:
a first power conductor under and electrically connected to the second source/drain contact; and
a second power conductor over and electrically connected to the third source/drain contact.

8. The semiconductor structure of claim 1, further comprising:
a bottom dielectric layer under and attached to the first source/drain feature.

9. The semiconductor structure of claim 8, further comprising:
a SiGe layer under and attached to the bottom dielectric layer.

10. The semiconductor structure of claim 8, further comprising:
a dielectric layer under and attached to the bottom dielectric layer and the gate structure.

11. A semiconductor structure, comprising:
a first active area and a second active area extending in a first direction;
an isolation feature between the first active area and the second active area in a second direction perpendicular to the first direction;
a gate structure across the first active area and the second active area and interfacing a top surface of the isolation feature;
source/drain features on opposite sides of the gate structure;
a first source/drain contact electrically connected to a first one of the source/drain features, wherein the first source/drain contact comprises a first portion and a second portion under the first portion and surrounded by the first one of the source/drain features; and
a second source/drain contact electrically connected to a second one of the source/drain features, wherein the second source/drain contact comprises a third portion and a fourth portion over the third portion and surrounded by the second one of the source/drain features.

12. The semiconductor structure of claim 11, further comprising:
interposing layers including nitrogen and surrounding sidewalls of the first portion of the first source/drain contact and the third portion of second source/drain contact.

13. The semiconductor structure of claim 12, further comprising:
silicide layers between the second portion of the first source/drain contact and the first one of the source/drain features and between the fourth portion of the second source/drain contact and the second one of the source/drain features.

14. The semiconductor structure of claim 11, further comprising:
a silicon substrate under and attached to the gate structure; and
an inter-metal dielectric layer under the silicon substrate, wherein the second source/drain contact passing through the silicon substrate and the inter-metal dielectric layer.

15. The semiconductor structure of claim 11, further comprising:
a dielectric layer attached to a bottom surface of the gate structure and sidewalls of the isolation feature, wherein the second source/drain contact passing through the dielectric layer.

16. The semiconductor structure of claim 15, further comprising:
a bottom dielectric layer between the first source/drain feature and the dielectric layer.

17. The semiconductor structure of claim 16, further comprising:
a SiGe layer between the bottom dielectric layer and the dielectric layer.

18. A semiconductor structure, comprising:
channel layers over a substrate;
a gate structure interfacing at least three surfaces of each of the channel layers;
gate spacers on opposite sides of the gate structure in a first direction;
a first source/drain feature and a second source/drain feature attached to the channel layers;
gate isolation features attached to the gate structure and gate spacers in a second direction perpendicular to the first direction, wherein bottom surfaces of the gate isolation features are lower than a bottom surface of the gate structure;
a frontside source/drain contact over and electrically connected to the first source/drain feature;
a first silicide layer between the frontside source/drain contact and the first source/drain feature, wherein a bottom surface of the first silicide layer is lower than a topmost channel layer of the channel layers;
a backside source/drain contact under and electrically connected to the second source/drain feature; and
a second silicide layer between the backside source/drain contact and the second source/drain feature, wherein a top surface of the second silicide layer is higher than a bottommost channel layer of the channel layers.

19. The semiconductor structure of claim 18, further comprising:
inner spacers between the channel layers and the substrate; and
interposing layers between and attached to the backside source/drain contact and the inner spacers.

20. The semiconductor structure of claim 18, further comprising:
a power conductor under and electrically connected to the second source/drain contact.
